(19) United States
(12) Patent Application Publication
(10) Pub. No.: US 2025/0125251 A1
(43) Pub. Date: Apr. 17, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Li-Ling Su, Taichung County (TW); Chia-Wei Su, Taoyuan City (TW); Tsu-Chun Kuo, Hsinchu County (TW); Wei-Hao Liao, New Taipei City (TW); Hsin-Ping Chen, Hsinchu County (TW); Yung-Hsu Wu, Taipei City (TW); Ming-Han Lee, Taipei City (TW); Shin-Yi Yang, New Taipei City (TW); Chih Wei LU, Hsinchu City (TW); Hsi-Wen Tien, Hsinchu County (TW); Meng-Pei Lu, Hsinchu City (TW)

(73) Assignee: Taiwan Semiconductor Manufacturing Company, Ltd., Hsinchu (TW)

(21) Appl. No.: 18/488,028

(22) Filed: Oct. 16, 2023

(51) Int. Cl. H01L 23/522; H01L 21/768

(52) U.S. Cl. CPC H01L 23/5226; H01L 21/76804

(57) ABSTRACT

A semiconductor device includes a semiconductor substrate, a gate structure, strained layers, source/drain contact patterns, a gate contact via, and source/drain contact vias. The gate structure is disposed over the semiconductor substrate. The strained layers are disposed aside the gate structure. The source/drain contact patterns are disposed on and electrically connected to the strained layers. Top surfaces of the source/drain contact patterns are coplanar with a top surface of the gate structure. The gate contact via is disposed on and electrically connected to the gate structure. The source/drain contact vias are disposed on and electrically connected to the source/drain contact patterns.

### BACKGROUND

As the semiconductor devices keep scaling down in size, three-dimensional multi-gate structures, such as the fin-type field effect transistor (FinFET), have been developed to replace planar CMOS devices. A characteristic of the FinFET device lies in that the structure has one or more silicon-based fins that are wrapped around by the gate to define the channel of the device. The gate wrapping structure further provides better electrical control over the channel.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1M are schematic cross-sectional views illustrating a manufacturing method of a semiconductor device in accordance with some embodiments of the disclosure.

FIG. 2A to FIG. 2E are schematic top views of FIG. 1H to FIG. 1L.

FIG. 3 is a three-dimensional view of the gate contact via in FIG. 1J.

FIG. 4A to FIG. 4F are schematic cross-sectional views illustrating a manufacturing method of a semiconductor device in accordance with some alternative embodiments of the disclosure.

FIG. 5A to FIG. 5E are schematic top views of FIG. 4A to FIG. 4E.

FIG. 6A to FIG. 6D are schematic cross-sectional views illustrating a manufacturing method of a semiconductor device in accordance with some alternative embodiments of the disclosure.

FIG. 7A to FIG. 7C are schematic top views of FIG. 6A to FIG. 6C.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

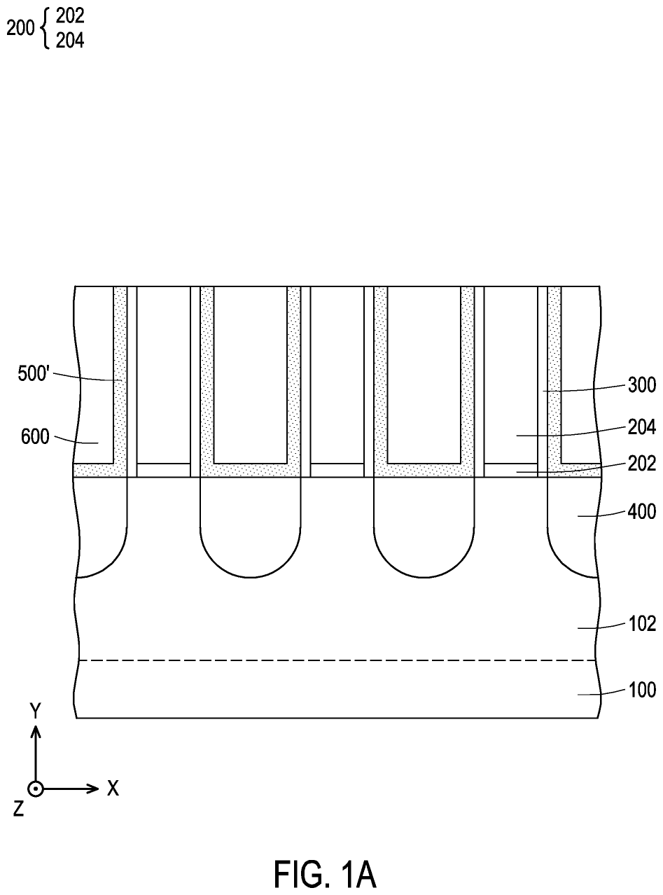

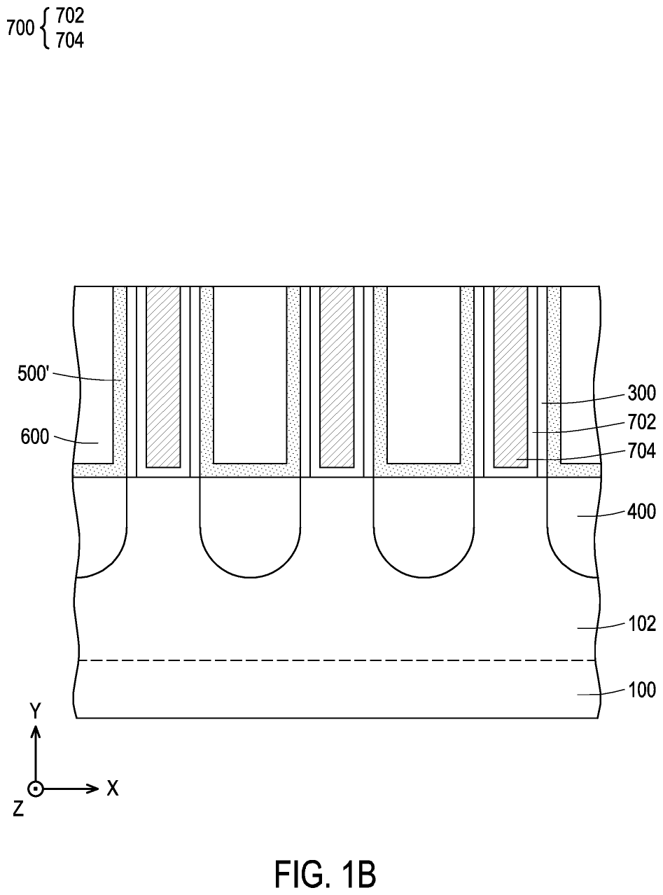

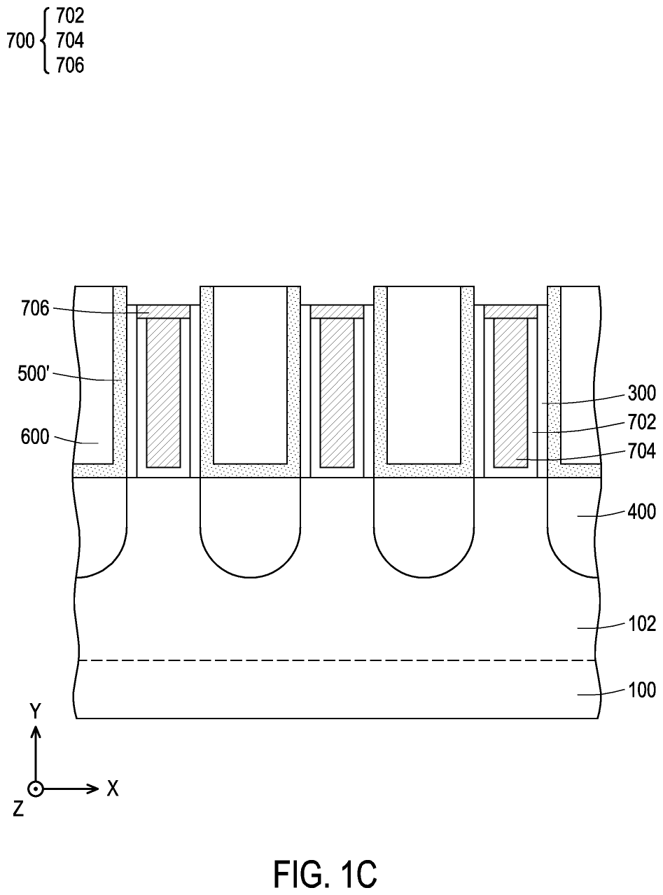

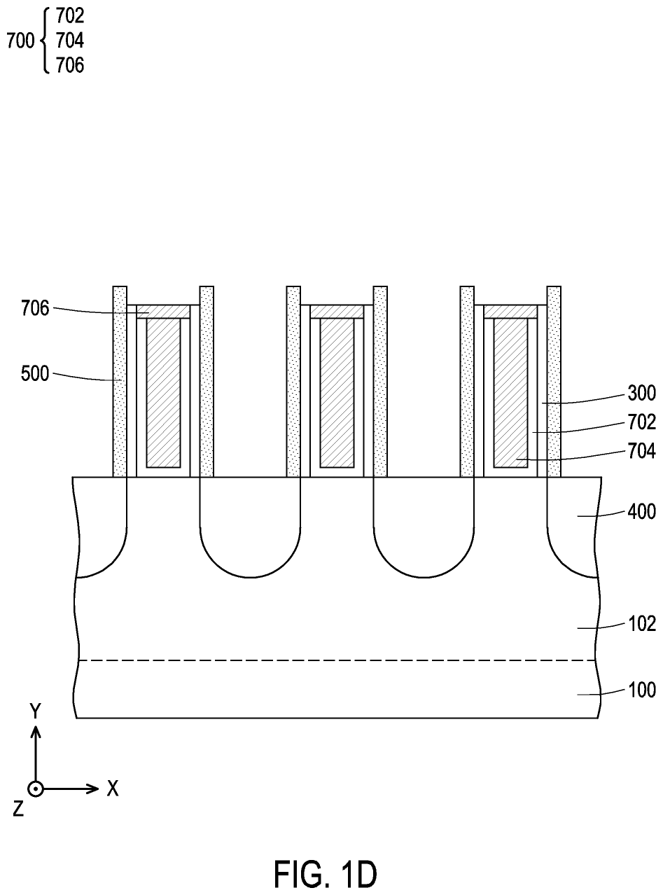

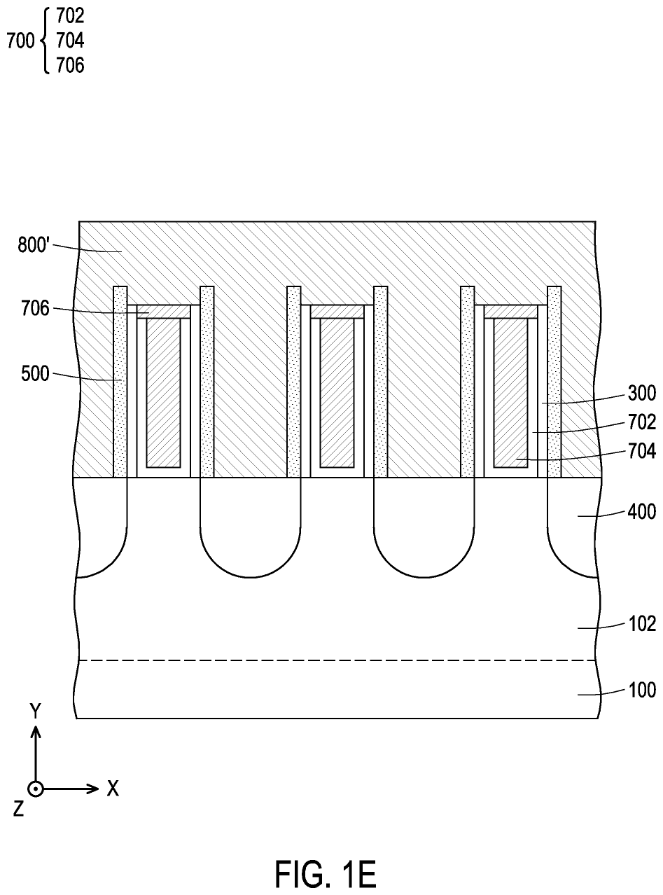

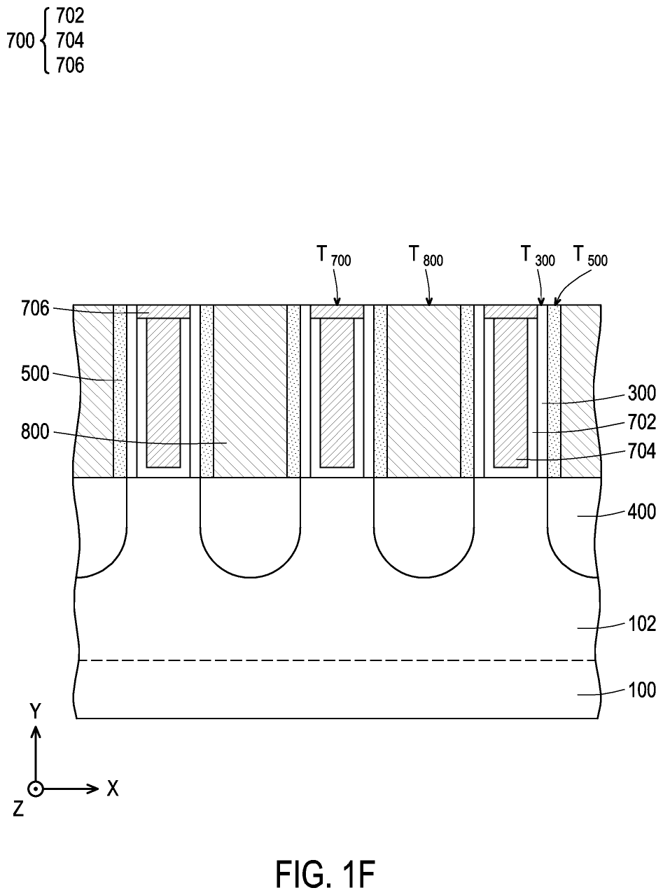

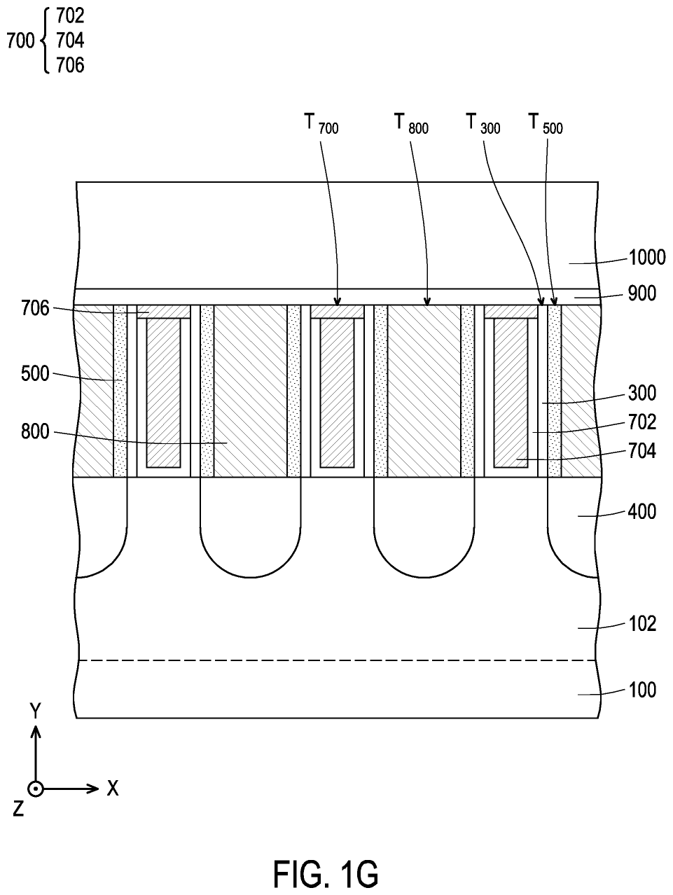

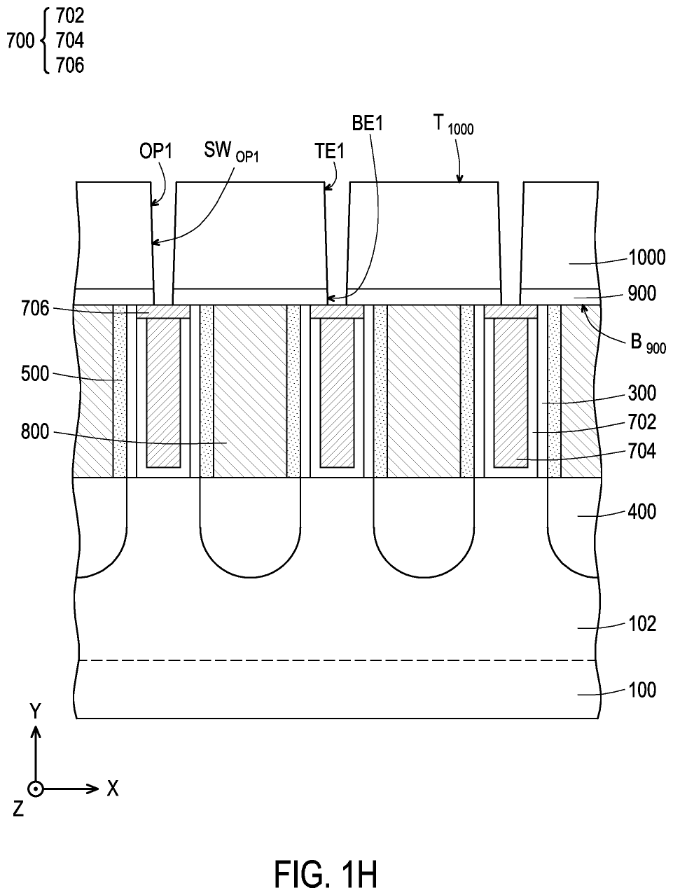

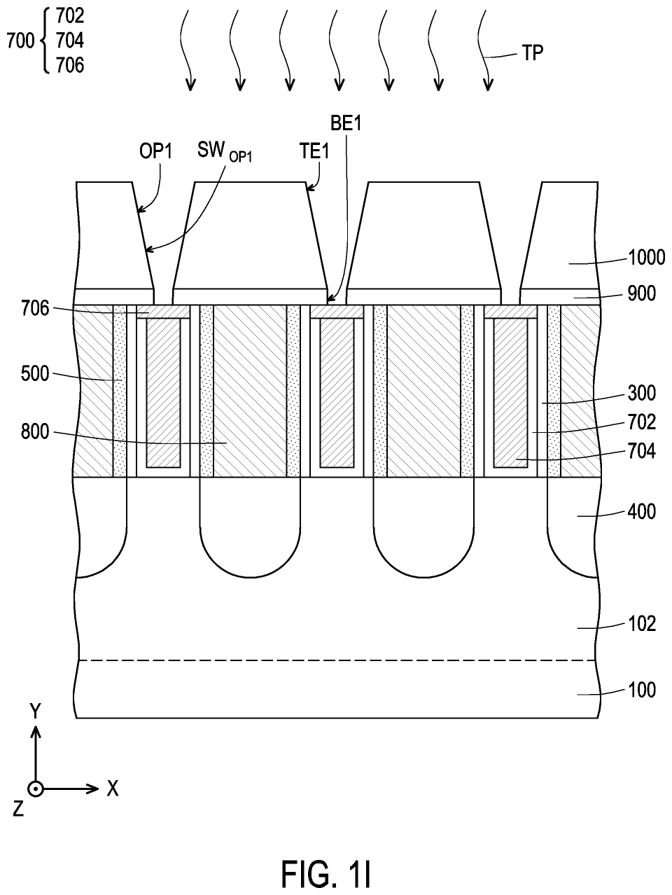

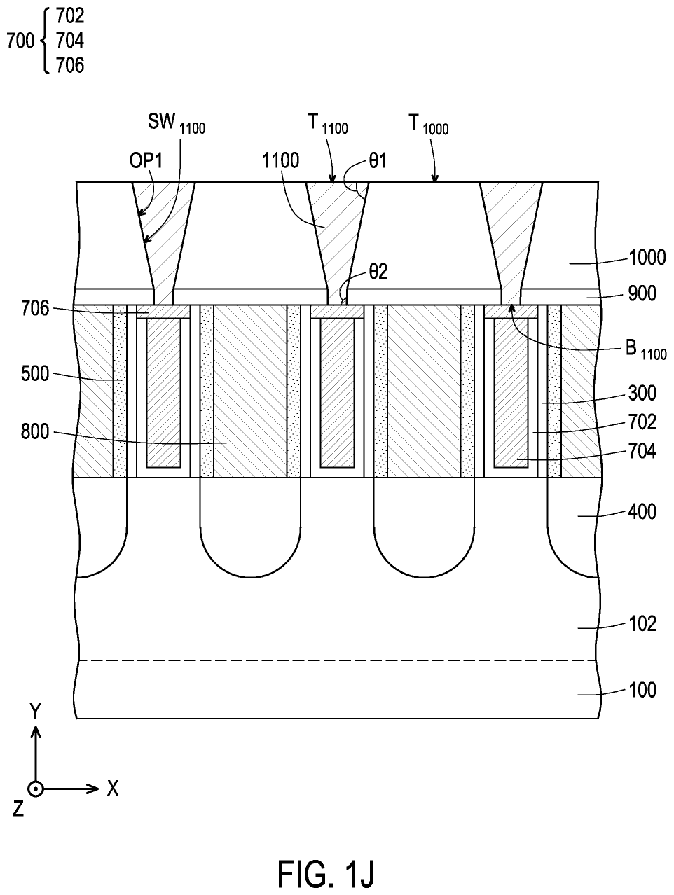

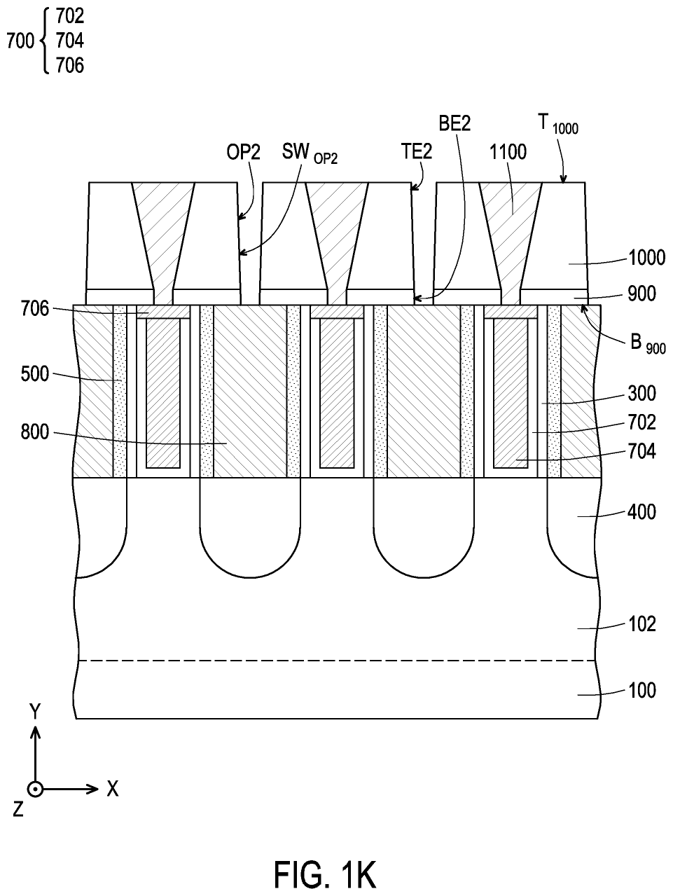

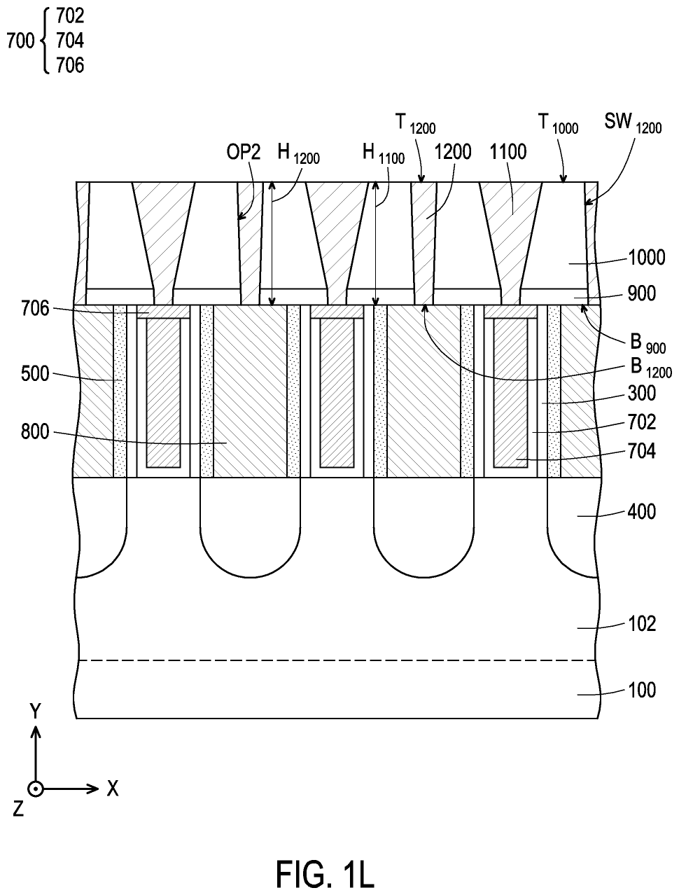

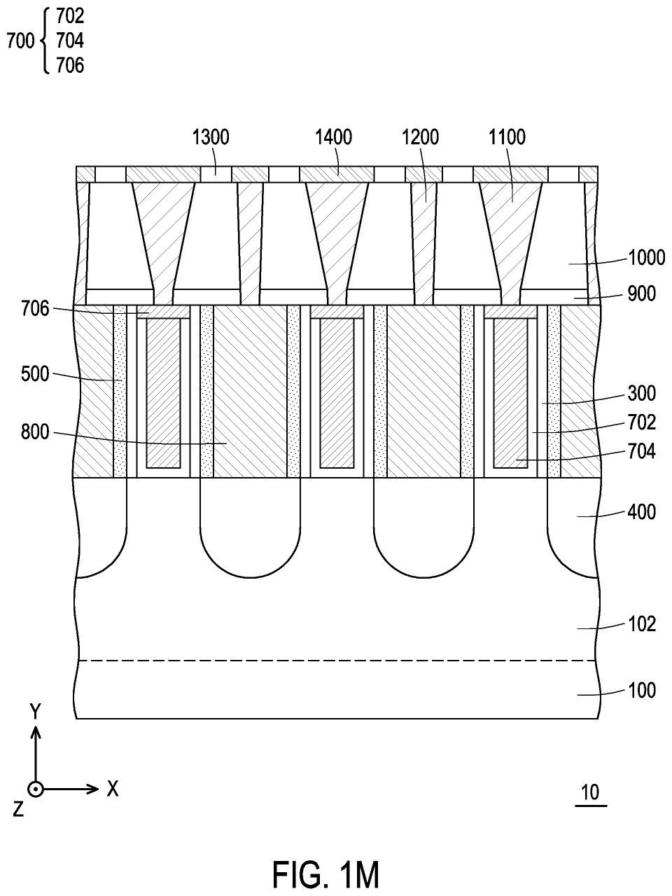

FIG. 1A to FIG. 1M are schematic cross-sectional views illustrating a manufacturing method of a semiconductor device 10 in accordance with some embodiments of the disclosure. Referring to FIG. 1A, a semiconductor substrate 100 is provided. In some embodiments, the semiconductor substrate 100 is a bulk semiconductor substrate, a semiconductor-on-insulator (SOI) substrate, or the like. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used.

In some embodiments, the semiconductor substrate 100 includes a crystalline silicon substrate (e.g., wafer). In some alternative embodiments, the semiconductor substrate 100 may be made of some other suitable elemental semiconductor, such as diamond or germanium; a suitable compound semiconductor, such as gallium arsenide, silicon carbide, gallium phosphide, indium phosphide, indium arsenide, and/or indium antimonide; or a suitable alloy semiconductor, such as SiGe, GaAsP, AlInAs, AlGaAs, GaInAs, GaInP, and/or GaInAsP. The semiconductor substrate 100 may include various doped regions depending on design requirements (e.g., p-type semiconductor substrate or n-type semiconductor substrate). In some embodiments, the doped regions may be doped with p-type or n-type dopants. For example, the doped regions may be doped with p-type dopants, such as boron or BF₂; n-type dopants, such as phosphorus or arsenic; and/or a combination thereof. Depending on the dopant type, an n-type FinFET or a p-type FinFET may be formed on the semiconductor substrate 100 in the subsequent processes. In some embodiments, the dopant concentration in various doped regions may be different.

In some embodiments, a plurality of fins 102 protrudes out from the semiconductor substrate 100. In some embodiments, the fins 102 extend along the X-direction. In some embodiments, the fins 102 are formed by patterning the semiconductor substrate 100. For example, the semiconductor substrate 100 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a semiconductor substrate 100 and patterned using a photolithography process. Spacers are formed alongside the patterned sacrificial layer using a self-aligned process. The sacrificial layer is then removed, and the remaining spacers may then be used to pattern the semiconductor substrate 100 to obtain the fins 102.

In some embodiments, an isolation layer (not shown) is formed on the semiconductor substrate 100. For example, the isolation layer is formed to cover lower portion of each fin 102. Meanwhile, the isolation layer exposes upper portion of each fin 102. In some embodiments, the isolation layer is formed of silicon oxide, silicon nitride, silicon oxynitride, a spin-on dielectric material, or a low-k dielectric material. The low-k dielectric materials are generally referring to dielectric materials having a dielectric constant lower than 3.9. The isolation layer may be formed by High Density Plasma Chemical Vapor Deposition (HDPCVD), Sub Atmospheric Chemical Vapor Deposition (SACVD), spin-on, or other suitable processes. In some embodiments, the isolation layer is referred to as a “Shallow Trench Isolation (STI)” structure.

As illustrated in FIG. 1A, a plurality of dummy gate structures 200 is formed over the semiconductor substrate 100. For example, the dummy gate structures 200 are formed across the fins 102. In some embodiments, the dummy gate structures 200 extend in a direction different from (e.g., perpendicular to) the extending direction of the fins 102. For example, the dummy gate structures 200 extend along the Z-direction. In some embodiments, each dummy gate structure 200 includes a dummy gate dielectric layer 202 and a dummy gate 204 disposed on the dummy gate dielectric layer 202. In some embodiments, the dummy gate dielectric layer 202 includes silicon oxide, silicon nitride, or silicon oxy-nitride. The dummy gate dielectric layer 202 may be formed using a suitable process, such as Atomic Layer Deposition (ALD), Chemical Vapor Deposition (CVD), Physical Vapor Deposition (PVD), thermal oxidation, UV-ozone oxidation, or a combination thereof. The dummy gate dielectric layer 202 may be formed to separate the fins 202 and the dummy gate 204 and to function as an etch stop layer.

In some embodiments, each dummy gate 204 may be a single-layered structure or a multi-layered structure. In some embodiments, the dummy gates 204 include a silicon-containing material, such as poly-silicon, amorphous silicon, or a combination thereof. The dummy gates 204 may be formed by a suitable process, such as ALD, CVD, PVD, plating, or a combination thereof.

In addition to the dummy gate structures 200, multiple pairs of spacers 300 are also formed over the fins 102. As illustrated in FIG. 1A, the spacers 300 are disposed on sidewalls of the dummy gate structures 200. For example, the dummy gate dielectric layer 202 and the dummy gate 204 are sandwiched between a pair of spacers 300. In some embodiments, the spacers 300 and the dummy gate structures 200 have the same extending direction. That is, the spacers 300 extend along the Z-direction. Similar to the dummy gate structures 200, the spacers 300 are also formed across the fins 102. In some embodiments, the spacers 300 are formed of dielectric materials, such as silicon oxide, silicon nitride, carbonized silicon nitride (SiCN), SiCON, or a combination thereof. In some embodiments, the spacers 300 may be formed by a thermal oxidation or a deposition followed by an anisotropic etch. It should be noted that the spacers 300 may be a single-layered structure or a multi-layered structure.

Thereafter, a plurality of strained layers 400 is formed aside the dummy gates 200. In some embodiments, the strained layers 400 may be doped with a conductive dopant. In some embodiments, the strained layers 400, such as SiGe, SiGeB, Ge, GeSn, or the like, are epitaxial-grown with p-type dopants for straining a p-type FinFET. That is, the strained layers 400 are doped with the p-type dopants to be the source and the drain of the p-type FinFET. The p-type dopants include boron or BF₂. In some alternative embodiments, the strained layers 400, such as SiC, SiP, SiCP, a combination of SiC/SiP, or the like, are epitaxial-grown with n-type dopants for straining an n-type FinFET. That is, the strained layers 400 are doped with the n-type dopants to be the source and the drain of the n-type FinFET. The n-type dopants include arsenic and/or phosphorus. Depending on the type of the device, the strained layers 400 in different regions may be doped with different type of dopants. Similarly, depending on the function of the device, the strained layers 400 in different regions may be doped with different dopant concentrations. In some embodiments, each of the strained layers 400 may be a single-layered structure or a multi-layered structure. In some embodiments, the method of forming the strained layers 400 includes forming recesses in the fins 102 and growing epitaxy layers from the recesses. In some embodiments, the strained layers 400 are referred to as “source/drain regions.”

Afterwards, a dielectric layer 600 is formed over the semiconductor substrate 100 aside or around the dummy gate structures 200. In some embodiments, the dielectric layer 600 includes oxide such as silicon oxide, phosphosilicate glass (PSG), borosilicate glass (BSG), boron-doped phosphosilicate glass (BPSG), a combination thereof, or the like. In some embodiments, an etch stop layer 500′ is formed after the step of forming the strained layers 400 and before the step of forming the dielectric layer 600. In some embodiments, the etch stop layer 500′ includes silicon oxide, silicon nitride, silicon carbo-nitride, or the like. In some embodiments, the etch stop layer 500′ is referred to as a “contact etch stop layer (CESL).” In some embodiments, after the step of forming the strained layers 400, an etch stop material layer and a dielectric material layer are formed on the semiconductor substrate 100 to fill up gaps between the dummy gate structures 200 by a suitable deposition technique such as spin-coating, CVD, HDPCVD, PVD, SACVD, molecular layer deposition (MLD), ALD, a combination thereof, or the like. Thereafter, the etch stop material layer and the dielectric material layer are planarized by a suitable technique such as chemical mechanical polishing (CMP) until top surfaces of the dummy gate structures 200 are exposed, so as to form the etch stop layer 500′ and the dielectric layer 600. In some embodiments, top surfaces of the dielectric layer 600 and the etch stop layer 500′ are substantially coplanar with the top surfaces of the dummy gate structures 200.

Referring to FIG. 1A and FIG. 1B, the dummy gate structures 200 are removed to form hollows exposing a portion of the fins 102. For example, the dummy gate dielectric layer 202 and the dummy gate 204 between two adjacent spacers 300 are removed. In some embodiments, the exposed portion of the fins 102 may act as channel regions of the fins 102. In some embodiments, the dummy gate structures 200 are removed through an etching process or other suitable processes. The etching process includes, for example, a wet etching process or a dry etching process. Example of the wet etching process includes chemical etching and example of the dry etching process includes plasma etching. However, other commonly known etching methods may also be utilized to remove the dummy gate structures 200. In some embodiments, during the etching process of the dummy gate 204, the underlying dummy gate dielectric layer 202 may act as an etch stop layer. The dummy gate dielectric layer 202 may be removed after the removal of the dummy gate 204.

After the dummy gate structures 200 are removed, a gate dielectric layer 702 and a gate 704 are filled into the hollows to form a plurality of gate structures 700. In some embodiments, the gate structures 700 extend in a direction the same as the extending direction of the dummy gate structures 200. Meanwhile, the gate structures 700 extend in a direction different from (e.g., perpendicular to) the extending direction of the fins 102. For example, the gate structures 700 extend along the Z-direction. In some embodiments, the gate structures 700 are disposed over the semiconductor substrate 100. For example, the gate structures 700 are disposed on the channel regions of the fins 102. As illustrated in FIG. 1B, the gate dielectric layer 702 covers a bottom surface and sidewalls of the gate 704. In other words, the gate dielectric layer 702 exhibits a U-shape in the cross-sectional view of FIG. 1B. In some embodiments, each of the gate structures 700 is disposed between two adjacent spacers 300. Meanwhile, the strained layers 400 are disposed aside the gate structures 700. In some embodiments, a material of the gate dielectric layer 702 may be identical to or different from the material of the dummy gate dielectric layer 202. For example, the gate dielectric layer 702 includes silicon oxide, silicon nitride, silicon oxy-nitride, high-K dielectric materials, or a combination thereof. High-K dielectric materials include metal oxides such as oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. The gate dielectric layer 702 is formed using a suitable process such as ALD, CVD, PVD, flowable chemical vapor deposition (FCVD), thermal oxidation, UV-ozone oxidation, or a combination thereof. The gate dielectric layer 702 may further include an interfacial layer (not shown). For example, the interfacial layer may be used in order to create a good interface between the fins 102 and the gates 704, as well as to suppress the mobility degradation of the channel carrier of the semiconductor device. Moreover, the interfacial layer may be formed by a thermal oxidation process, a CVD process, or an ALD process. A material of the interfacial layer includes a dielectric material. For example, the interfacial layer may be a silicon oxide layer or a silicon oxynitride layer.

A material of the gate 704 includes metal, metal alloy, or metal nitride. For example, the gate 704 includes TiN, WN, TaN, Ru, Ti, Ag, Al, TiAl, TiAIN, TaC, TaCN, TaSiN, Mn, or Zr. Moreover, the gate 704 may further include a barrier layer, a work function layer, or a combination thereof. In some embodiments, a liner layer, a seed layer, an adhesion layer, or a combination thereof may be included between the gates 704 and the fins 102.

The steps illustrated in FIG. 1A to FIG. 1B are commonly referred to as a “metal gate replacement process.” In some embodiments, the dummy gate structures 200 including polysilicon are replaced by the gate structures 700 which include metal.

Referring to FIG. 1B and FIG. 1C, a portion of the gate dielectric layers 702, a portion of the gates 704, and a portion of the spacers 300 are removed. In some embodiments, the portion of the gate dielectric layers 702, the portion of the gates 704, and the portion of the spacers 300 are removed through an etching process or other suitable processes. The etching process includes, for example, a wet etching process or a dry etching process. Example of the wet etching process includes chemical etching and example of the dry etching process includes plasma etching. Due to etching selectivity, the removal rates of the gate dielectric layers 702 and the gates 704 are greater than the removal rate of the spacers 300. As such, after removal, top surfaces of the gate dielectric layers 702 and top surfaces of the gates 704 are located at a level height lower than that of top surfaces of the spacers 300.

Thereafter, capping layers 706 are formed on the remaining gate dielectric layers 702 and the remaining gates 704. For example, each of the capping layers 706 is formed between two adjacent spacers 300. In some embodiments, the capping layers 706 are made of a metal material such as tungsten, cobalt, copper, titanium, or the like. In some embodiments, the capping layers 706 are formed by, for example, electro-chemical plating process, CVD, PECVD, ALD, PVD, a combination thereof, or the like. In some embodiments, the capping layers 706 are formed to protect the gates 704 from being damaged by the subsequent processes. In some embodiments, the capping layers 706 are considered as part of the gate structures 700. In other words, each gate structure 700 includes the gate dielectric layer 702, the gate 704, and the capping layer 706.

Referring to FIG. 1C and FIG. 1D, the dielectric layer 600 and a portion of the etch stop layer 500′ are removed to expose the underlying strained layers 400. In some embodiments, the dielectric layer 600 and the portion of the etch stop layer 500′ are removed by an etching process or other suitable processes. The etching process includes, for example, a wet etching process or a dry etching process. Example of the wet etching process includes chemical etching and example of the dry etching process includes plasma etching. Upon removal of the portion of the etch stop layer 500′, the etch stop layer 500′ is divided into a plurality of etch stop patterns 500.

Referring to FIG. 1E, a source/drain contact pattern material layer 800′ is formed on the spacers 300, the strained layers 400, the etch stop patterns 500, and the gate structures 700. For example, the source/drain contact pattern material layer 800′ is in physical contact with the spacers 300, the strained layers 400, the etch stop patterns 500, and the gate structures 700. In some embodiments, a material of the source/drain contact pattern material layer 800′ includes copper, copper alloys, nickel, aluminum, manganese, magnesium, silver, gold, tungsten, a combination thereof, or the like. The source/drain contact pattern material layer 800′ may be formed by, for example, electro-chemical plating process, CVD, PECVD, ALD, PVD, a combination thereof, or the like.

Referring to FIG. 1E and FIG. 1F, a planarization process is performed on the source/drain contact pattern material layer 800′ until the gate structures 700 are revealed. In some embodiments, a portion of the source/drain contact pattern material layer 800′ is removed to form a plurality of source/drain contact patterns 800. The planarization process includes, for example, a CMP process, an etch back process, a combination thereof, or the like. In some embodiments, during the planarization process, a portion of each etch stop pattern 500 is also removed. In some embodiments, after the planarization process, top surfaces T₇₀₀ of the gate structures 700 are coplanar with top surfaces T₈₀₀ of the source/drain contact patterns 800. Meanwhile, the top surfaces T₇₀₀ of the gate structures 700 and the top surfaces T₈₀₀ of the source/drain contact patterns 800 are also coplanar with top surfaces T₃₀₀ of the spacers 300 and top surfaces T₅₀₀ of the etch stop patterns 500. In other words, the top surfaces T₃₀₀ of the spacers 300, the top surfaces T₅₀₀ of the etch stop patterns 500, the top surfaces T₇₀₀ of the gate structures 700, and the top surfaces T₈₀₀ of the source/drain contact patterns 800 are located at the same level height.

As illustrated in FIG. 1F, each source/drain contact pattern 800 is sandwiched between two adjacent etch stop patterns 500. In some embodiments, the source/drain contact patterns 800 are disposed aside the gate structures 700. In other words, each of the gate structures 700 is located between two adjacent source/drain contact patterns 800. In some embodiments, the source/drain contact patterns 800 are disposed on and electrically connected to the strained layers 400. For example, the source/drain contact patterns 800 are in physical contact with the strained layers 400 to render electrical connection with the strained layers 400.

As mentioned above, the top surfaces T₃₀₀ of the spacers 300, the top surfaces T₅₀₀ of the etch stop patterns 500, the top surfaces T₇₀₀ of the gate structures 700, and the top surfaces T₈₀₀ of the source/drain contact patterns 800 are located at the same level height. Therefore, a combination of the top surfaces T₃₀₀ of the spacers 300, the top surfaces T₅₀₀ of the etch stop patterns 500, the top surfaces T₇₀₀ of the gate structures 700, and the top surfaces T₈₀₀ of the source/drain contact patterns 800 is a flat and smooth surface. This flat and smooth surface allows the elements subsequently formed thereon to be formed easily with better precision control.

Referring to FIG. 1G, an etch stop layer 900 and a dielectric layer 1000 are sequentially deposited on the spacers 300, the etch stop patterns 500, the gate structures 700, and the source/drain contact patterns 800. For example, the etch stop layer 900 and the dielectric layer 1000 are directly formed on the flat and smooth surface constituted by the top surfaces T₃₀₀ of the spacers 300, the top surfaces T₅₀₀ of the etch stop patterns 500, the top surfaces T₇₀₀ of the gate structures 700, and the top surfaces T₈₀₀ of the source/drain contact patterns 800.

In some embodiments, the etch stop layer 900 includes silicon oxide, silicon nitride, silicon carbo-nitride, or the like. The etch stop layer 900 may be deposited using, for example, spin-coating, CVD, HDPCVD, PVD, SACVD, MLD, ALD, a combination thereof, or the like. In some embodiments, the etch stop layer 900 is formed to have a thickness ranging from about 30 Å to about 100 Å. In some embodiments, the etch stop layer 900 is referred to as a “contact etch stop layer (CESL).”

In some embodiments, the dielectric layer 1000 includes oxide such as silicon oxide, PSG, BSG, BPSG, a combination thereof, or the like. The dielectric layer 1000 may be deposited using, for example, spin-coating, FCVD, CVD, HDPCVD, PVD, SACVD, MLD, ALD, a combination thereof, or the like. In some embodiments, the dielectric layer 1000 is formed to have a thickness ranging from about 100 Å to about 200 Å.

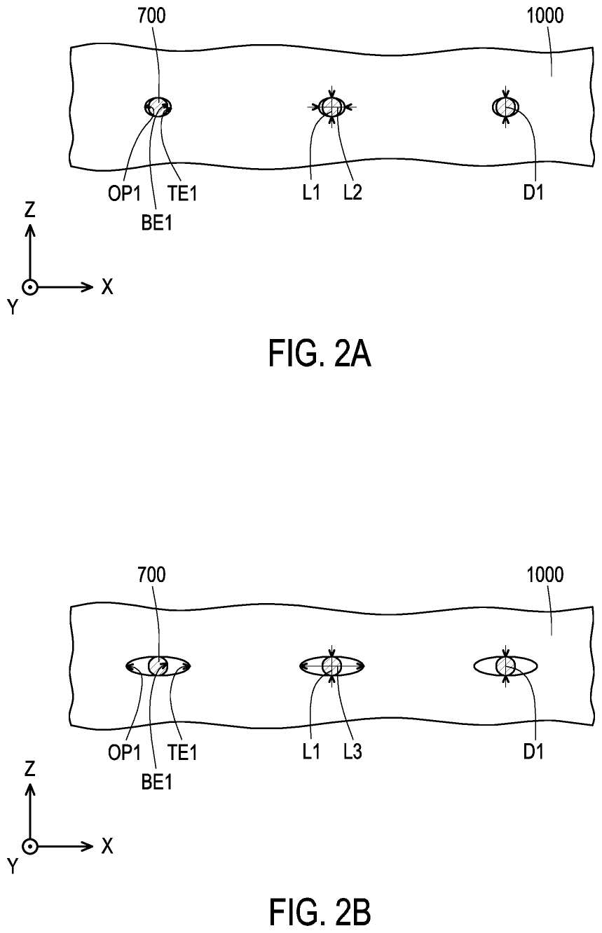

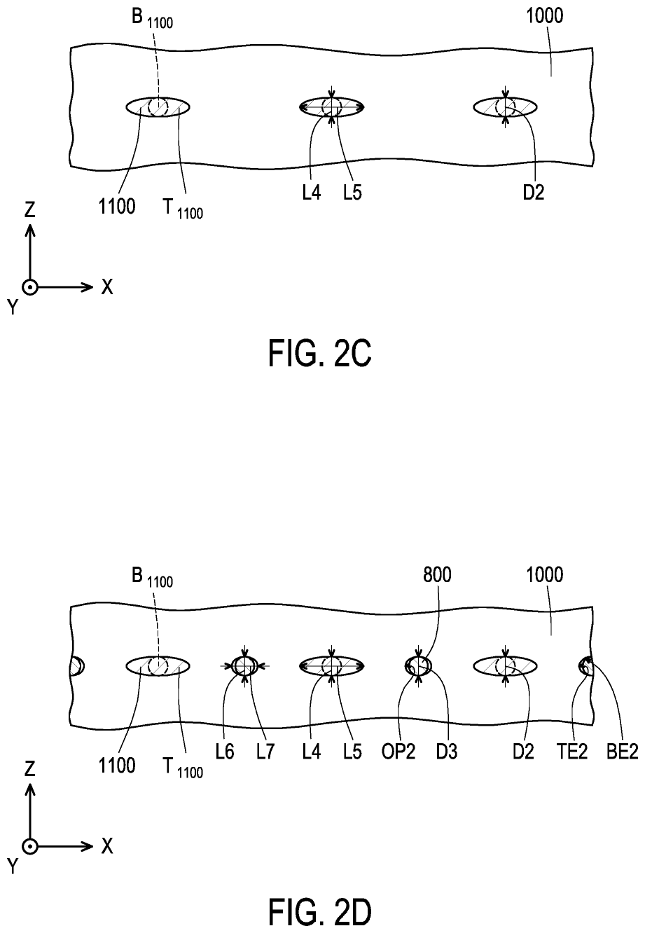

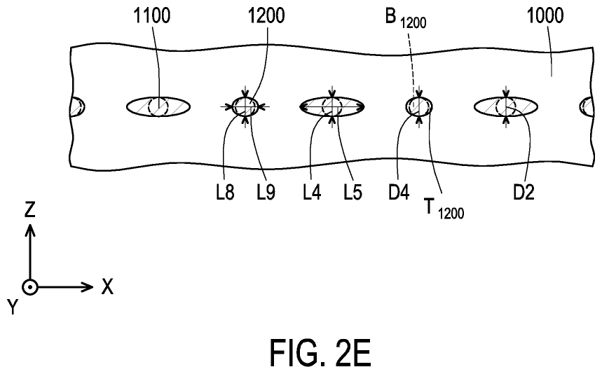

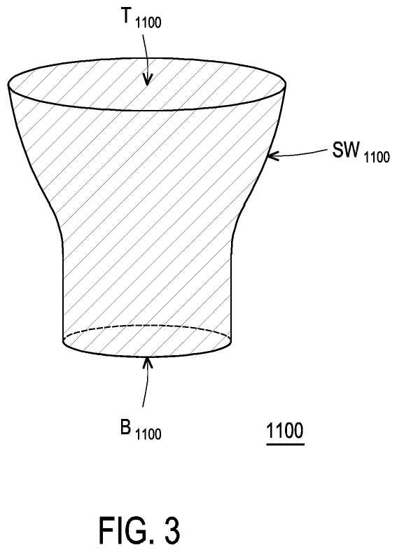

Referring to FIG. 1H to FIG. 1L, a plurality of gate contact vias 1110 and a plurality of source/drain contact vias 1200 are formed. The detailed configuration and formation method of the gate contact vias 1110 and the source/drain contact vias 1200 will be discussion below in conjunction with FIG. 1H to FIG. 1L, FIG. 2A to FIG. 2E, and FIG. 3.

FIG. 2A to FIG. 2E are schematic top views of FIG. 1H to FIG. 1L. Referring to FIG. 1H and FIG. 2A, a plurality of openings OP1 is formed in the etch stop layer 900 and the dielectric layer 1000. In some embodiments, the openings OP1 are formed to penetrate through the etch stop layer 900 and the dielectric layer 1000. In some embodiments, each opening OP1 has a bottom end BE1 and a top end TE1 opposite to the bottom end BE1. The top end TEL is in proximity to a top surface T₁₀₀₀ of the dielectric layer 1000 while the bottom end BE1 is in proximity to a bottom surface B₉₀₀ of the etch stop layer 900. In some embodiments, the locations of the openings OP1 correspond to the locations of the gate structures 700. For example, the bottom end BE1 of each opening OP1 exposes at least a portion of the corresponding gate structure 700. That is, the bottom end BE1 of each opening OP1 exposes at least a portion of the corresponding capping layer 706.

In some embodiments, sidewalls SW_{OP1} of each opening OP1 are substantially straight with a slight inclination with respect to the top surface T₁₀₀₀ of the dielectric layer 1000 and/or the bottom surface T₉₀₀ of the etch stop layer 900. Due to this slight inclination, the bottom end BE1 of each opening OP1 is circular while the top end TE1 of each opening OP1 is elliptical, as shown in FIG. 2A. In some embodiments, the top end TEL is concentric with the bottom end BE1 in each opening OP1. In some embodiments, the bottom end BE1 of each opening OP1 has a diameter D1. On the other hand, the top end TE1 of each opening OP1 has a short-axis L1 extending along the Z-direction and a long-axis L2 extending along the X-direction. As illustrated in FIG. 2A, a length of the short-axis L1 of the top end TE1 is substantially equal to the diameter D1 of the bottom end BE1. Meanwhile, a length of the long-axis L2 of the top end TE1 is slightly greater than the diameter D1 of the bottom end BE1. In some embodiments, a ratio of an area of the bottom end BE1 of the opening OP1 to an area of the top end T1 of the opening OP1 ranges from about 1:1.01 to about 1:1.05.

In some embodiments, each opening OP1 in FIG. 1H and FIG. 2A is formed by a lithography process followed by an etching process. The etching process includes, for example, a wet etching process or a dry etching process. Example of the wet etching process includes chemical etching and example of the dry etching process includes plasma etching. The plasma etching process includes inductively coupled plasma (ICP) etching, capacitive coupled plasma (CCP) etching, or the like. When the etching is performed by ICP etching or CCP etching, the power and the bias supplied are respectively about 100 W to about 2000 W and about 0 W to about 1200 W. Meanwhile, the etching gas includes HBr, Cl₂, H₂, CH₄, N₂, He, Ne, Kr, CF₄, CHF₃, CH₃F, CH₂F₂, C₄F₈, C₄F₆, SF₆, N₂, O₂, Ar, a combination thereof, or the like.

Referring to FIG. 1H to FIG. 1I and FIG. 2A to FIG. 2B, the top end TE1 of each opening OP1 is enlarged. In some embodiments, a treating process TP is performed on the dielectric layer 1000 to remove a portion of the dielectric layer 1000 in proximity to the top end TE1 of each opening OP1, so as to enlarge the top end TEL of each opening OP1. In some embodiments, the treating process TP includes reactive ion beam etching. In some embodiments, the power and the bias supplied during the reactive ion beam etching are respectively about 100 W to about 1000 W and about 0 kV to about 12 kV. Meanwhile, the etching gas includes He, Ne, Kr, Ar, CF₄, CHF₃, CH₃F, CH₂F₂, C₄F₈, C₄F₆, SF₆, O₂, a combination thereof, or the like. In some embodiments, since the reactive ion beam etching is an anisotropic etching, the enlargement of the openings OP1 is a one-directional enlargement. For example, as shown in FIG. 2B, the top end TE1 of each opening OP1 has the short-axis L1 extending along the Z-direction and a long-axis L3 extending along the X-direction. As shown in FIG. 2A and FIG. 2B, the length of the short-axis L1 remains unchanged while a length of the long-axis L3 in FIG. 2B is greater than the length of the long-axis L2 in FIG. 2A. In other words, the enlargement of the top end TE1 of each opening OP1 is only along the X-direction. It should be noted that the treating process TP does not affect the bottom end BE1 of each opening OP1. In other words, the size and the shape of the bottom end BE1 of each opening OP1 remain unchanged. As shown in FIG. 2B, the top end TE1 is concentric with the bottom end BE1 in each opening OP1. In some embodiments, the length of the short-axis L1 of the top end TEL is substantially equal to the diameter D1 of the bottom end BE1. Meanwhile, a length of the long-axis L3 of the top end TE1 is greater than the diameter D1 of the bottom end BE1. For example, the length of the long-axis L3 of the top end TE1 is greater than the diameter D1 of the bottom end BE1 by about 2 nm to about 6 nm. In some embodiments, after enlargement, a ratio of an area of the bottom end BE1 of the opening OP1 to an area of the top end TE1 of the opening OP1 ranges from about 1:1.2 to about 1:2. In some embodiments, after the treating process TP, the sidewalls SW_{OP1} of each opening OP1 are no longer straight. For example, at least of a portion of each sidewall SW_{OP1} is curved, and each opening OP1 has a funnel shape.

Referring to FIG. 1J and FIG. 2C, a conductive material is filled into the openings OP1 to form the gate contact vias 1100 in the openings OP1. In some embodiments, the conductive material includes metal or metal alloys, such as W, Cu, Co, Ni, Al, Rh, Ir, Ru, Mo, Os, Ag, Au, CuAl, NiAl, RuAl, VNi, VPt, AlSc, a combination thereof, or the like. In some embodiments, the conductive material is deposited into the openings OP1 through PVD, ion beam deposition (IBD), CVD, ALD, molecular beam epitaxy (MBE), electro-chemical plating (ECP), electroless deposition (ELD), or the like. In some embodiments, in order to ensure the adhesion, an adhesion layer may be included in each gate contact via 1100. A material of the adhesion layer includes nitride or oxide compounds of T, Ta, Mn, Nb, Cr, V, and Y.

In some embodiments, the gate contact vias 1100 are disposed on and electrically connected to the gate structures 700. For example, the gate contact vias 1100 penetrate through the dielectric layer 1000 and the etch stop layer 900 to be in physical contact with the gate structures 700 to render electrical connection with the gate structures 700. The detailed shape of each gate contact via 1100 will be discussed below in conjunction with FIG. 1J, FIG. 2C, and FIG. 3.

FIG. 3 is a three-dimensional view of the gate contact via 1110 in FIG. 1J. In some embodiments, each gate contact via 1100 has a bottom surface B₁₁₀₀, a top surface T₁₁₀₀ opposite to the bottom surface B₁₁₀₀, and sidewalls SW₁₁₀₀ connecting the top surface T₁₁₀₀ and the bottom surface B₁₁₀₀. As illustrated in FIG. 1J, the bottom surface B 1100 of each gate contact via 1100 is in physical contact with the corresponding gate structure 700. For example, the bottom surface B₁₁₀₀ of each gate contact via 1100 is in physical contact with the corresponding capping layer 706. Meanwhile, the top surface T₁₁₀₀ of each gate contact via 1100 is coplanar with the top surface T₁₀₀₀ of the dielectric layer 1000. As illustrated in FIG. 2C, the bottom surface B₁₁₀₀ of each gate contact via 1100 is circular in a top view, and the top surface T₁₁₀₀ of each gate contact via 1100 is elliptical in the top view. In some embodiments, the top surface T₁₁₀₀ is concentric with the bottom surface B 1100 in each gate contact via 1100. In some embodiments, the bottom surface B₁₁₀₀ of each gate contact via 1100 has a diameter D2. On the other hand, the top surface T₁₁₀₀ of each gate contact via 1100 has a short-axis L4 extending along the Z-direction and a long-axis L5 extending along the X-direction. As illustrated in FIG. 2C, a length of the short-axis L4 of the top surface T₁₁₀₀ is substantially equal to the diameter D2 of the bottom surface B₁₁₀₀. Meanwhile, a length of the long-axis L5 of the top surface T₁₁₀₀ is greater than the diameter D2 of the bottom surface T₁₁₀₀. For example, the length of the long-axis L5 of the top surface T₁₁₀₀ is greater than the diameter D2 of the bottom surface T₁₁₀₀ by about 2 nm to about 6 nm. In some embodiments, a ratio of an area of the bottom surface B₁₁₀₀ of the gate contact via 1100 to an area of the top surface T₁₁₀₀ of the gate contact via 1100 ranges from about 1:1.2 to about 1:2.

In some embodiments, since the gate contact vias 1100 are formed by filling up the openings OP1, a contour of each gate contact via 1100 is substantially identical to a contour of each opening OP1. For example, as illustrated in FIG. 3, at least of a portion of each sidewall SW₁₁₀₀ is curved, and each gate contact via 1100 has a funnel shape. As illustrated in FIG. 1J, an included angle θ1 between the top surface T₁₁₀₀ and the sidewall SW₁₁₀₀ of each gate contact via 1100 ranges from about 65° to about 80°, and an included angle θ2 between the bottom surface B₁₁₀₀ and the sidewall SW₁₁₀₀ of each gate contact via 1100 ranges from about 87° to about 90°.

As mentioned above, after the treating process TP, the top end TE1 of each opening OP1 is enlarged. As such, the process window for filling the conductive material into the openings OP1 to form the gate contact vias 1100 is enlarged, and the process complexity may be simplified. In addition, the enlarged top ends TE1 render the gate contact vias 1100 to have larger top surfaces T₁₁₀₀. In other words, the contact area between the gate contact vias 1100 and the subsequently formed elements may be increased. As such, the contact resistance may be lowered to improve the device performance.

Referring to FIG. 1K and FIG. 2D, a plurality of openings OP2 is formed in the etch stop layer 900 and the dielectric layer 1000. In some embodiments, the openings OP2 are formed to penetrate through the etch stop layer 900 and the dielectric layer 1000. In some embodiments, each opening OP2 has a bottom end BE2 and a top end TE2 opposite to the bottom end BE2. The top end TE2 is in proximity to the top surface T₁₀₀₀ of the dielectric layer 1000 while the bottom end BE2 is in proximity to the bottom surface B₉₀₀ of the etch stop layer 900. In some embodiments, the locations of the openings OP2 correspond to the locations of the source/drain contact patterns 800. For example, the bottom end BE2 of each opening OP2 exposes at least a portion of the corresponding source/drain contact pattern 800.

In some embodiments, sidewalls SW_{OP2} of each opening OP2 are substantially straight with a slight inclination with respect to the top surface T₁₀₀₀ of the dielectric layer 1000 and/or the bottom surface T₉₀₀ of the etch stop layer 900. Due to this slight inclination, the bottom end BE2 of each opening OP2 is circular while the top end TE2 of each opening OP2 is elliptical, as shown in FIG. 2D. In some embodiments, the top end TE2 is concentric with the bottom end BE2 in each opening OP2. In some embodiments, the bottom end BE2 of each opening OP2 has a diameter D3. On the other hand, the top end TE2 of each opening OP2 has a short-axis L6 extending along the Z-direction and a long-axis L7 extending along the X-direction. As illustrated in FIG. 2D, a length of the short-axis L6 of the top end TE2 is substantially equal to the diameter D3 of the bottom end BE2. Meanwhile, a length of the long-axis L7 of the top end TE2 is slightly greater than the diameter D3 of the bottom end BE2. In some embodiments, a ratio of an area of the bottom end BE2 of the opening OP2 to an area of the top end TE2 of the opening OP2 ranges from about 1:1.01 to about 1:1.05. In some embodiments, each opening OP2 is formed by similar process as that of the openings OP1 in FIG. 1H and FIG. 2A, so the detailed description thereof is omitted therein.

Referring to FIG. 1L and FIG. 2E, a conductive material is filled into the openings OP2 to form the source/drain contact vias 1200 in the openings OP2. In some embodiments, a material of the source/drain contact vias 1200 may be the same as or different from the material of the gate contact vias 1100. In some embodiments, the conductive material includes metal or metal alloys, such as W, Cu, Co, Ni, Al, Rh, Ir, Ru, Mo, Os, Ag, Au, CuAl, NiAl, RuAl, VNi, VPt, AlSc, a combination thereof, or the like. In some embodiments, the conductive material is deposited into the openings OP2 through PVD, IBD, CVD, ALD, MBE, ECP, ELD, or the like. In some embodiments, in order to ensure the adhesion, an adhesion layer may be included in each source/drain contact via 1200. A material of the adhesion layer includes nitride or oxide compounds of T, Ta, Mn, Nb, Cr, V, and Y.

In some embodiments, the source/drain contact vias 1200 are disposed on and electrically connected to the source/drain contact patterns 800. For example, the source/drain contact vias 1200 penetrate through the dielectric layer 1000 and the etch stop layer 900 to be in physical contact with the source/drain contact patterns 800 to render electrical connection with the source/drain contact patterns 800. As illustrated in FIG. 1L, a height H₁₁₀₀ of each gate contact via 1100 is substantially equal to a height H₁₂₀₀ of each source/drain contact via 1200.

In some embodiments, each source/drain contact via 1200 has a bottom surface B₁₂₀₀, a top surface T₁₂₀₀ opposite to the bottom surface B₁₂₀₀, and sidewalls SW₁₂₀₀ connecting the top surface T₁₂₀₀ and the bottom surface B₁₂₀₀. As illustrated in FIG. 1L, the bottom surface B₁₂₀₀ of each source/drain contact via 1200 is in physical contact with the corresponding source/drain contact pattern 800. Meanwhile, the top surface T₁₂₀₀ of each source/drain contact via 1200 is coplanar with the top surface T₁₀₀₀ of the dielectric layer 1000. As illustrated in FIG. 2E, the bottom surface B₁₂₀₀ of each source/drain contact via 1200 is circular in a top view, and the top surface T₁₂₀₀ of each source/drain contact via 1200 is elliptical in the top view. In some embodiments, the top surface T₁₂₀₀ is concentric with the bottom surface T₁₂₀₀ in each source/drain contact via 1200. In some embodiments, the bottom surface B₁₂₀₀ of each source/drain contact via 1200 has a diameter D4. On the other hand, the top surface T₁₂₀₀ of each source/drain contact via 1200 has a short-axis L8 extending along the Z-direction and a long-axis L9 extending along the X-direction. As illustrated in FIG. 2E, a length of the short-axis L8 of the top surface T₁₂₀₀ is substantially equal to the diameter D4 of the bottom surface B₁₂₀₀. Meanwhile, a length of the long-axis L9 of the top surface T₁₂₀₀ is slightly greater than the diameter D4 of the bottom surface T₁₂₀₀. In some embodiments, a ratio of an area of the bottom surface B₁₂₀₀ of the source/drain contact via 1200 to an area of the top surface T₁₂₀₀ of the source/drain contact via 1200 ranges from about 1:1.01 to about 1:1.05.

In some embodiments, since the source/drain contact vias 1200 are formed by filling up the openings OP2, a contour of each source/drain contact via 1200 is substantially identical to a contour of each opening OP2. For example, sidewalls SW₁₂₀₀ of each source/drain contact via 1200 are substantially straight with a slight inclination with respect to the top surface T₁₀₀₀ of the dielectric layer 1000 and/or the bottom surface T₉₀₀ of the etch stop layer 900.

As illustrated in FIG. 2E, the diameter D2 of the bottom surface B 1100 of each gate contact via 1100 is substantially equal to the diameter D4 of the bottom surface B₁₂₀₀ of each source/drain contact via 1200. Similarly, the length of the short-axis L4 of the top surface T₁₁₀₀ of each gate contact via 1100 is substantially equal to the length of the short-axis L8 of the top surface T₁₂₀₀ of each source/drain contact via 1200. On the other hand, the length of the long-axis L5 of the top surface T₁₁₀₀ of each gate contact via 1100 is greater than the length of the long-axis L9 of the top surface T₁₂₀₀ of each source/drain contact via 1200.

Referring to FIG. 1M, a dielectric layer 1300 and a plurality of routing patterns 1400 are formed on the dielectric layer 1000, the gate contact vias 1100, and the source/drain contact vias 1200 to obtain the semiconductor device 10. In some embodiments, the dielectric layer 1300 includes oxide such as silicon oxide, PSG, BSG, BPSG, a combination thereof, or the like. The dielectric layer 1300 may be deposited using, for example, spin-coating, FCVD, CVD, HDPCVD, PVD, SACVD, MLD, ALD, a combination thereof, or the like.

As illustrated in FIG. 1M, the routing patterns 1400 are embedded in the dielectric layer 1300. In some embodiments, the routing patterns 1400 are electrically connected to the gate contact vias 1100 and the source/drain contact vias 1200. For example, the routing patterns 1400 are in physical contact with the gate contact vias 1100 and the source/drain contact vias 1200 to render electrical connection with the gate contact vias 1100 and the source/drain contact vias 1200. In some embodiments, the routing patterns 1400 includes copper, copper alloys, nickel, aluminum, manganese, magnesium, silver, gold, tungsten, a combination of thereof, or the like. The routing patterns 1400 may be formed by, for example, electro-chemical plating process, CVD, PECVD, ALD, PVD, a combination thereof, or the like.

As mentioned above, the gate contact vias 1100 have larger top surfaces T₁₁₀₀. In other words, the contact area between the gate contact vias 1100 and the routing patterns 1400 may be increased. As such, the contact resistance may be lowered to improve the performance of the semiconductor device 10.

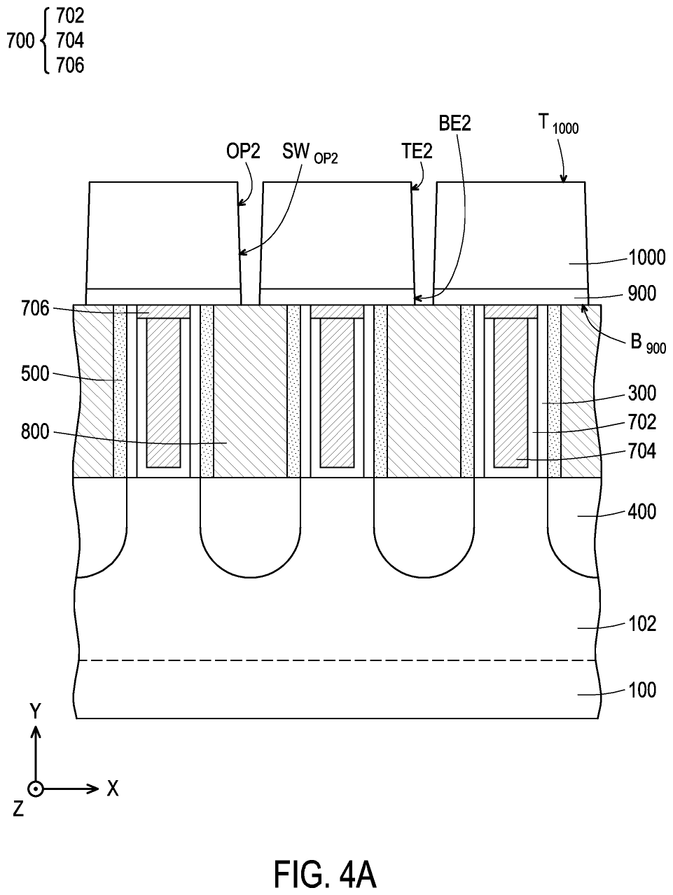

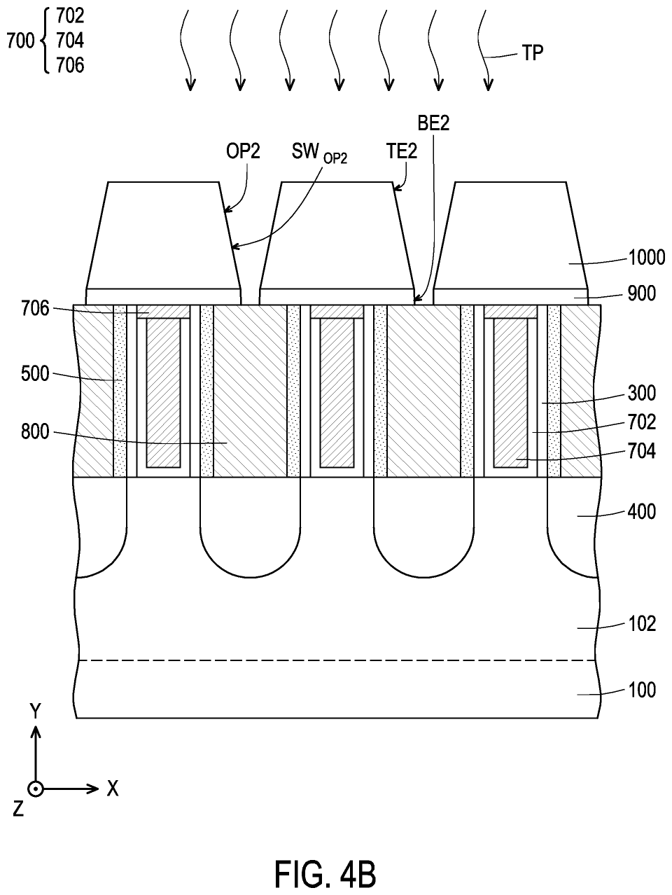

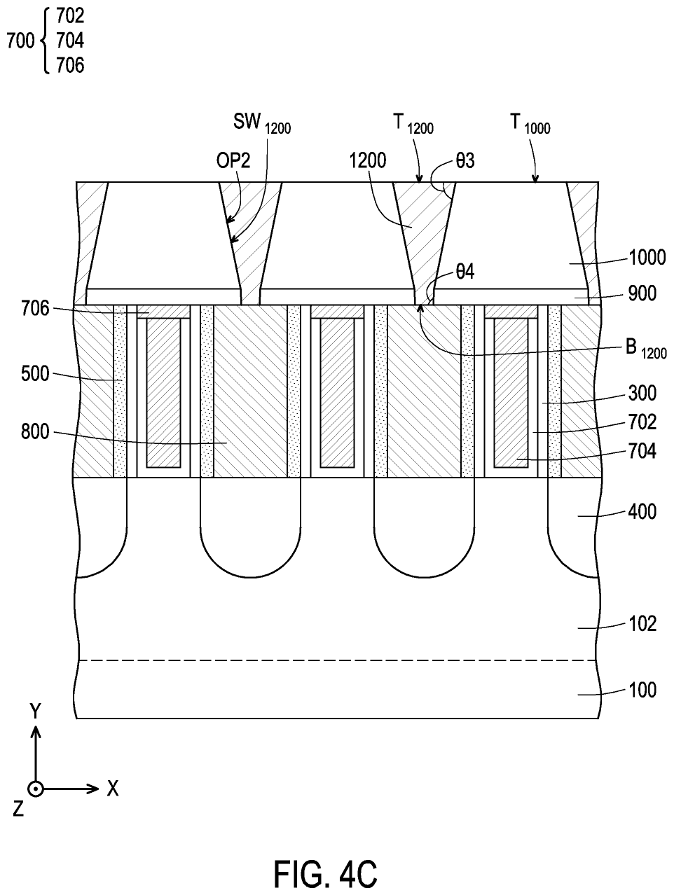

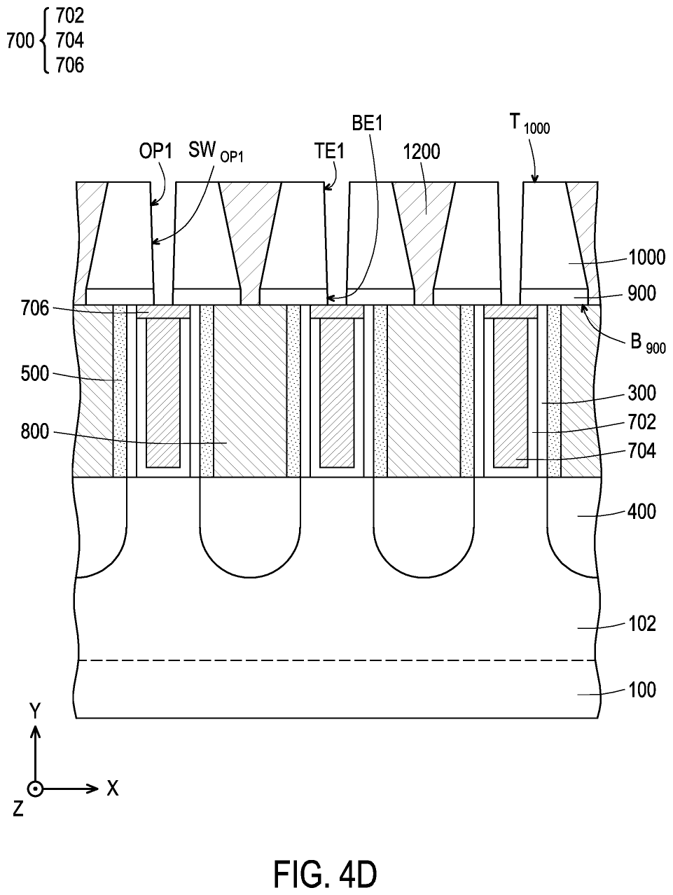

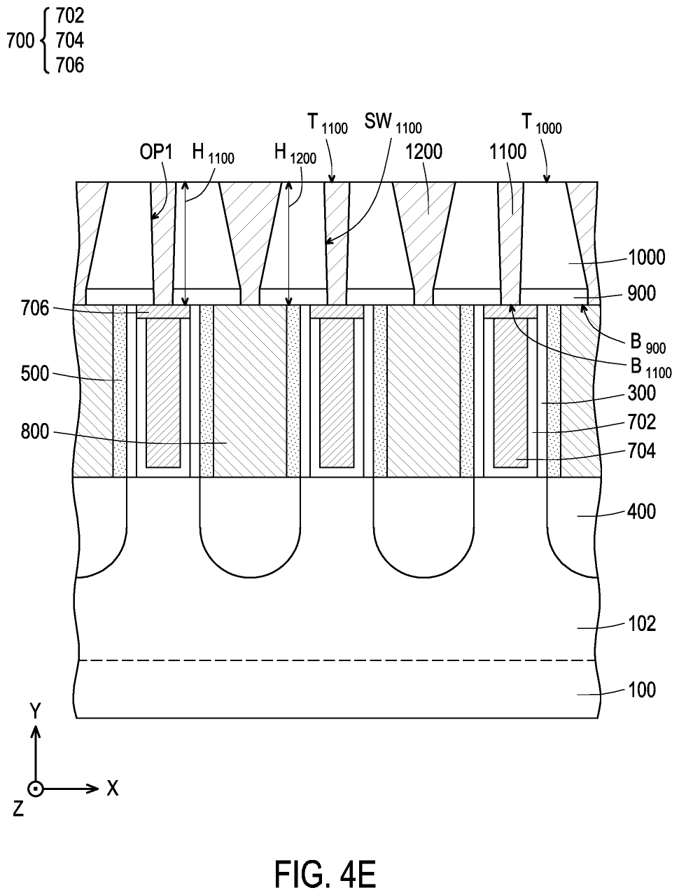

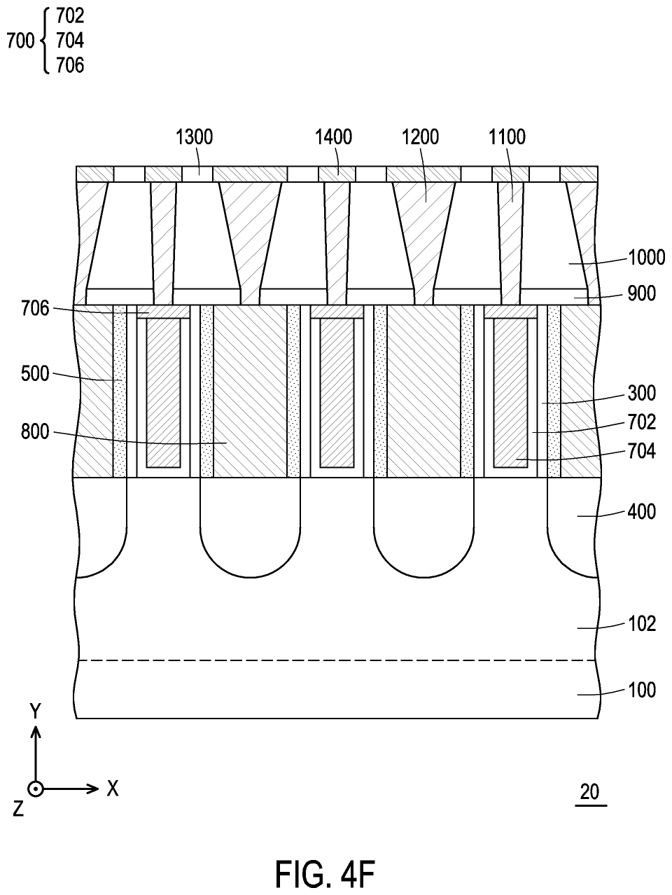

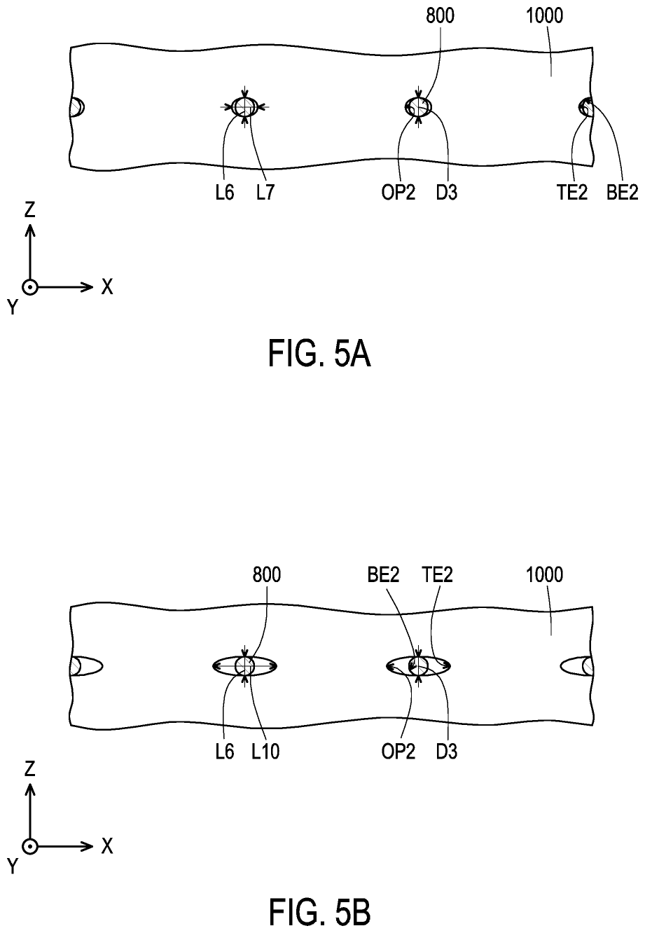

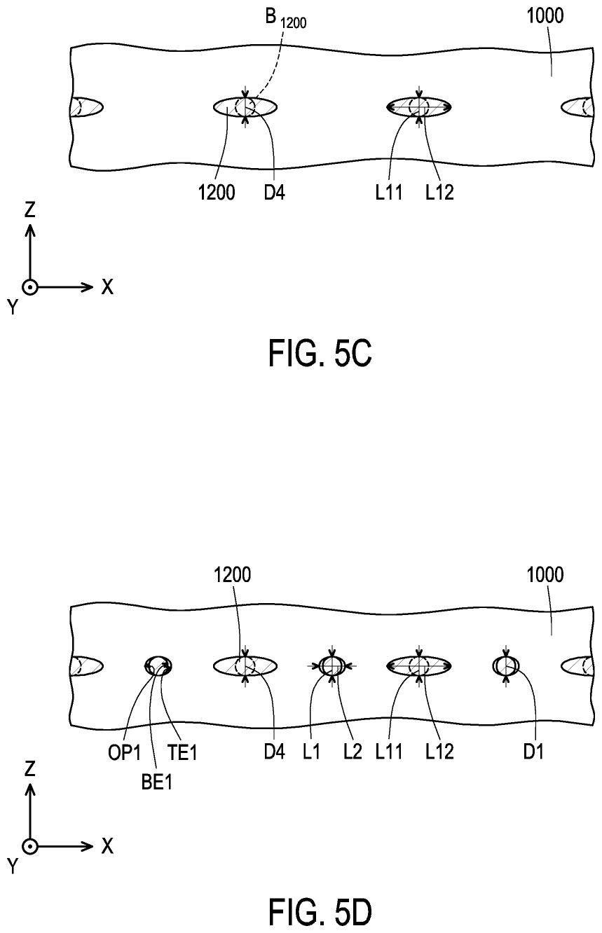

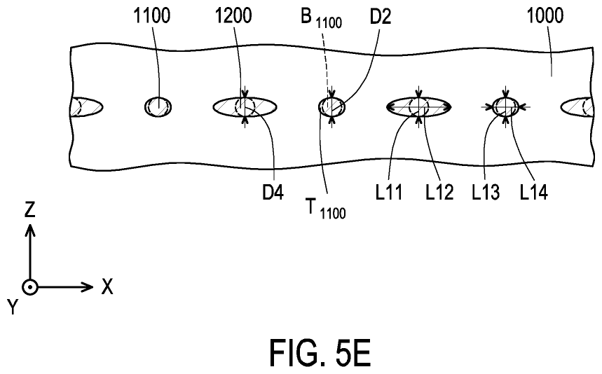

FIG. 4A to FIG. 4F are schematic cross-sectional views illustrating a manufacturing method of a semiconductor device 20 in accordance with some alternative embodiments of the disclosure. Referring to FIG. 4A to FIG. 4E, a plurality of gate contact vias 1110 and a plurality of source/drain contact vias 1200 are formed. The detailed configuration and formation method of the gate contact vias 1110 and the source/drain contact vias 1200 will be discussion below in conjunction with FIG. 4A to FIG. 4E and FIG. 5A to FIG. 5E.

FIG. 5A to FIG. 5E are schematic top views of FIG. 4A to FIG. 4E. Referring to FIG. 4A and FIG. 5A, similar processes as illustrated in FIG. 1A to FIG. 1G are performed. Thereafter, a plurality of openings OP2 is formed in the etch stop layer 900 and the dielectric layer 1000. In some embodiments, the openings OP2 are formed to penetrate through the etch stop layer 900 and the dielectric layer 1000. In some embodiments, each opening OP2 has a bottom end BE2 and a top end TE2 opposite to the bottom end BE2. The top end TE2 is in proximity to a top surface T₁₀₀₀ of the dielectric layer 1000 while the bottom end BE2 is in proximity to a bottom surface B₉₀₀ of the etch stop layer 900. In some embodiments, the locations of the openings OP2 correspond to the locations of the source/drain contact patterns 800. For example, the bottom end BE2 of each opening OP2 exposes at least a portion of the corresponding source/drain contact pattern 800.

In some embodiments, sidewalls SW_{OP2} of each opening OP2 are substantially straight with a slight inclination with respect to the top surface T₁₀₀₀ of the dielectric layer 1000 and/or the bottom surface T₉₀₀ of the etch stop layer 900. Due to this slight inclination, the bottom end BE2 of each opening OP2 is circular while the top end TE2 of each opening OP2 is elliptical, as shown in FIG. 5A. In some embodiments, the top end TE2 is concentric with the bottom end BE2 in each opening OP2. In some embodiments, the bottom end BE2 of each opening OP2 has a diameter D3. On the other hand, the top end TE2 of each opening OP2 has a short-axis L6 extending along the Z-direction and a long-axis L7 extending along the X-direction. As illustrated in FIG. 5A, a length of the short-axis L6 of the top end TE2 is substantially equal to the diameter D3 of the bottom end BE2. Meanwhile, a length of the long-axis L7 of the top end TE2 is slightly greater than the diameter D3 of the bottom end BE2. In some embodiments, a ratio of an area of the bottom end BE2 of the opening OP2 to an area of the top end TE2 of the opening OP2 ranges from about 1:1.01 to about 1:1.05.

In some embodiments, each opening OP2 in FIG. 4A and FIG. 5A is formed by a lithography process followed by an etching process. The etching process includes, for example, a wet etching process or a dry etching process. Example of the wet etching process includes chemical etching and example of the dry etching process includes plasma etching. The plasma etching process includes ICP etching, CCP etching, or the like. When the etching is performed by ICP etching or CCP etching, the power and the bias supplied are respectively about 100 W to about 2000 W and about 0 W to about 1200 W. Meanwhile, the etching gas includes HBr, Cl₂, H₂, CH₄, N₂, He, Ne, Kr, CF₄, CHF₃, CH₃F, CH₂F₂, C₄F₈, C₄F₆, SF₆, N₂, O₂, Ar, a combination thereof, or the like.

Referring to FIG. 4A to FIG. 4B and FIG. 5A to FIG. 5B, the top end TE2 of each opening OP2 is enlarged. In some embodiments, a treating process TP is performed on the dielectric layer 1000 to remove a portion of the dielectric layer 1000 in proximity to the top end TE2 of each opening OP2, so as to enlarge the top end TE2 of each opening OP2. In some embodiments, the treating process TP includes reactive ion beam etching. In some embodiments, the power and the bias supplied during the reactive ion beam etching are respectively about 100 W to about 1000 W and about 0 kV to about 12 kV. Meanwhile, the etching gas includes He, Ne, Kr, Ar, CF₄, CHF₃, CH₃F, CH₂F₂, C₄F₈, C₄F₆, SF₆, O₂, a combination thereof, or the like. In some embodiments, since the reactive ion beam etching is an anisotropic etching, the enlargement of the openings OP2 is a one-directional enlargement. For example, as shown in FIG. 5B, the top end TE2 of each opening OP2 has the short-axis L6 extending along the Z-direction and a long-axis L10 extending along the X-direction. As shown in FIG. 5A and FIG. 5B, the length of the short-axis L6 remains unchanged while a length of the long-axis L10 in FIG. 5B is greater than the length of the long-axis L7 in FIG. 5A. In other words, the enlargement of the top end TE2 of each opening OP2 is only along the X-direction. It should be noted that the treating process TP does not affect the bottom end BE2 of each opening OP2. In other words, the size and the shape of the bottom end BE2 of each opening OP2 remain unchanged. As shown in FIG. 5B, the top end TE2 is concentric with the bottom end BE2 in each opening OP2. In some embodiments, the length of the short-axis L6 of the top end TE2 is substantially equal to the diameter D3 of the bottom end BE2. Meanwhile, a length of the long-axis L10 of the top end TE2 is greater than the diameter D3 of the bottom end BE2. For example, the length of the long-axis L10 of the top end TE2 is greater than the diameter D3 of the bottom end BE2 by about 2 nm to about 6 nm. In some embodiments, after enlargement, a ratio of an area of the bottom end BE2 of the opening OP2 to an area of the top end TE2 of the opening OP2 ranges from about 1:1.2 to about 1:2. In some embodiments, after the treating process TP, the sidewalls SW_{OP2} of each opening OP2 are no longer straight. For example, at least of a portion of each sidewall SW_{OP2} is curved, and each opening OP2 has a funnel shape.

Referring to FIG. 4C and FIG. 5C, a conductive material is filled into the openings OP2 to form the source/drain contact vias 1200 in the openings OP2. In some embodiments, the conductive material includes metal or metal alloys, such as W, Cu, Co, Ni, Al, Rh, Ir, Ru, Mo, Os, Ag, Au, CuAl, NiAl, RuAl, VNi, VPt, AlSc, a combination thereof, or the like. In some embodiments, the conductive material is deposited into the openings OP2 through PVD, IBD, CVD, ALD, MBE, ECP, ELD, or the like. In some embodiments, in order to ensure the adhesion, an adhesion layer may be included in each source/drain contact via 1200. A material of the adhesion layer includes nitride or oxide compounds of T, Ta, Mn, Nb, Cr, V, and Y.

In some embodiments, the source/drain contact vias 1200 are disposed on and electrically connected to the source/drain contact patterns 800. For example, the source/drain contact vias 1200 penetrate through the dielectric layer 1000 and the etch stop layer 900 to be in physical contact with the source/drain contact patterns 800 to render electrical connection with the source/drain contact patterns 800.

In some embodiments, each source/drain contact via 1200 has a bottom surface B₁₂₀₀, a top surface T₁₂₀₀ opposite to the bottom surface B₁₂₀₀, and sidewalls SW₁₂₀₀ connecting the top surface T₁₂₀₀ and the bottom surface B₁₂₀₀. As illustrated in FIG. 4C, the bottom surface B₁₂₀₀ of each source/drain contact via 1200 is in physical contact with the corresponding source/drain contact pattern 800. Meanwhile, the top surface T₁₂₀₀ of each source/drain contact via 1200 is coplanar with the top surface T₁₀₀₀ of the dielectric layer 1000. As illustrated in FIG. 5C, the bottom surface B₁₂₀₀ of each source/drain contact via 1200 is circular in a top view, and the top surface T₁₂₀₀ of each source/drain contact via 1200 is elliptical in the top view. In some embodiments, the top surface T₁₂₀₀ is concentric with the bottom surface B₁₂₀₀ in each source/drain contact via 1200. In some embodiments, the bottom surface B₁₂₀₀ of each source/drain contact via 1200 has a diameter D4. On the other hand, the top surface T₁₂₀₀ of each source/drain contact via 1200 has a short-axis L11 extending along the Z-direction and a long-axis L12 extending along the X-direction. As illustrated in FIG. 5C, a length of the short-axis L11 of the top surface T₁₂₀₀ is substantially equal to the diameter D4 of the bottom surface B₁₂₀₀. Meanwhile, a length of the long-axis L12 of the top surface T₁₂₀₀ is greater than the diameter D4 of the bottom surface T₁₂₀₀. For example, the length of the long-axis L12 of the top surface T₁₂₀₀ is greater than the diameter D4 of the bottom surface T₁₂₀₀ by about 2 nm to about 6 nm. In some embodiments, a ratio of an area of the bottom surface B₁₂₀₀ of the source/drain contact via 1200 to an area of the top surface T₁₂₀₀ of the source/drain contact via 1200 ranges from about 1:1.2 to about 1:2.

In some embodiments, since the source/drain contact vias 1200 are formed by filling up the openings OP2, a contour of each source/drain contact via 1200 is substantially identical to a contour of each opening OP2. For example, at least of a portion of each sidewall SW₁₂₀₀ is curved, and each source/drain contact via 1200 has a funnel shape. As illustrated in FIG. 4C, an included angle θ3 between the top surface T₁₂₀₀ and the sidewall SW 1200 of each source/drain contact via 1200 ranges from about 65° to about 80°, and an included angle θ4 between the bottom surface B₁₂₀₀ and the sidewall SW₁₂₀₀ of each source/drain contact via 1200 ranges from about 87° to about 90°.

As mentioned above, after the treating process TP, the top end TE2 of each opening OP2 is enlarged. As such, the process window for filling the conductive material into the openings OP2 to form the source/drain contact vias 1200 is enlarged, and the process complexity may be simplified. In addition, the enlarged top ends TE2 render the source/drain contact vias 1200 to have larger top surfaces T₁₂₀₀. In other words, the contact area between the source/drain contact vias 1200 and the subsequently formed elements may be increased. As such, the contact resistance may be lowered to improve the device performance.

Referring to FIG. 4D and FIG. 5D, a plurality of openings OP1 is formed in the etch stop layer 900 and the dielectric layer 1000. In some embodiments, the openings OP1 are formed to penetrate through the etch stop layer 900 and the dielectric layer 1000. In some embodiments, each opening OP1 has a bottom end BE1 and a top end TE1 opposite to the bottom end BE1. The top end TE1 is in proximity to the top surface T₁₀₀₀ of the dielectric layer 1000 while the bottom end BE1 is in proximity to the bottom surface B₉₀₀ of the etch stop layer 900. In some embodiments, the locations of the openings OP1 correspond to the locations of the gate structures 700. For example, the bottom end BE1 of each opening OP1 exposes at least a portion of the corresponding gate structure 700. That is, the bottom end BE1 of each opening OP1 exposes at least a portion of the corresponding capping layer 706.

In some embodiments, sidewalls SW_{OP1} of each opening OP1 are substantially straight with a slight inclination with respect to the top surface T₁₀₀₀ of the dielectric layer 1000 and/or the bottom surface T₉₀₀ of the etch stop layer 900. Due to this slight inclination, the bottom end BE1 of each opening OP1 is circular while the top end TE1 of each opening OP1 is elliptical, as shown in FIG. 5D. In some embodiments, the top end TE1 is concentric with the bottom end BE1 in each opening OP1. In some embodiments, the bottom end BE1 of each opening OP1 has a diameter D1. On the other hand, the top end TE1 of each opening OP1 has a short-axis L1 extending along the Z-direction and a long-axis L2 extending along the X-direction. As illustrated in FIG. 5D, a length of the short-axis L1 of the top end TE1 is substantially equal to the diameter D1 of the bottom end BE1. Meanwhile, a length of the long-axis L2 of the top end TE1 is slightly greater than the diameter D1 of the bottom end BE1. In some embodiments, a ratio of an area of the bottom end BE1 of the opening OP1 to an area of the top end TE1 of the opening OP1 ranges from about 1:1.01 to about 1:1.05. In some embodiments, each opening OP1 is formed by similar process as that of the openings OP2 in FIG. 4A and FIG. 5A, so the detailed description thereof is omitted therein.

Referring to FIG. 4E and FIG. 5E, a conductive material is filled into the openings OP1 to form the gate contact vias 1100 in the openings OP1. In some embodiments, a material of the gate contact vias 1100 may be the same as or different from the material of the source/drain contact vias 1200. In some embodiments, the conductive material includes metal or metal alloys, such as W, Cu, Co, Ni, Al, Rh, Ir, Ru, Mo, Os, Ag, Au, CuAl, NiAl, RuAl, VNi, VPt, AlSc, a combination thereof, or the like. In some embodiments, the conductive material is deposited into the openings OP1 through PVD, IBD, CVD, ALD, MBE, ECP, ELD, or the like. In some embodiments, in order to ensure the adhesion, an adhesion layer may be included in each gate contact via 1100. A material of the adhesion layer includes nitride or oxide compounds of T, Ta, Mn, Nb, Cr, V, and Y.

In some embodiments, the gate contact vias 1100 are disposed on and electrically connected to the gate structures 700. For example, the gate contact vias 1100 penetrate through the dielectric layer 1000 and the etch stop layer 900 to be in physical contact with the gate structures 700 to render electrical connection with the gate structures 700. As illustrated in FIG. 4E, a height H₁₁₀₀ of each gate contact via 1100 is substantially equal to a height H₁₂₀₀ of each source/drain contact via 1200.

In some embodiments, each gate contact via 1100 has a bottom surface B₁₁₀₀, a top surface T₁₁₀₀ opposite to the bottom surface B₁₁₀₀, and sidewalls SW₁₁₀₀ connecting the top surface T₁₁₀₀ and the bottom surface B₁₁₀₀. As illustrated in FIG. 4E, the bottom surface B₁₁₀₀ of each gate contact via 1100 is in physical contact with the corresponding gate structure 700. For example, the bottom surface B₁₁₀₀ of each gate contact via 1100 is in physical contact with the corresponding capping layer 706. Meanwhile, the top surface T₁₁₀₀ of each gate contact via 1100 is coplanar with the top surface T₁₀₀₀ of the dielectric layer 1000. As illustrated in FIG. 5E, the bottom surface B₁₁₀₀ of each gate contact via 1100 is circular in a top view, and the top surface T₁₁₀₀ of each gate contact via 1100 is elliptical in the top view. In some embodiments, the top surface T₁₁₀₀ is concentric with the bottom surface B₁₁₀₀ in each gate contact via 1100. In some embodiments, the bottom surface B₁₁₀₀ of each gate contact via 1100 has a diameter D2. On the other hand, the top surface T₁₁₀₀ of each gate contact via 1100 has a short-axis L13 extending along the Z-direction and a long-axis L14 extending along the X-direction. As illustrated in FIG. 5E, a length of the short-axis L13 of the top surface T₁₁₀₀ is substantially equal to the diameter D2 of the bottom surface B₁₁₀₀. Meanwhile, a length of the long-axis L14 of the top surface T₁₁₀₀ is slightly greater than the diameter D2 of the bottom surface T₁₁₀₀. In some embodiments, a ratio of an area of the bottom surface B₁₁₀₀ of the gate contact via 1100 to an area of the top surface T₁₁₀₀ of the gate contact via 1100 ranges from about 1:1.01 to about 1:1.05.

In some embodiments, since the gate contact vias 1100 are formed by filling up the openings OP1, a contour of each gate contact via 1100 is substantially identical to a contour of each opening OP1. For example, sidewalls SW₁₁₀₀ of each gate contact via 1100 are substantially straight with a slight inclination with respect to the top surface T₁₀₀₀ of the dielectric layer 1000 and/or the bottom surface T₉₀₀ of the etch stop layer 900.

As illustrated in FIG. 5E, the diameter D4 of the bottom surface B₁₂₀₀ of each source/drain contact via 1200 is substantially equal to the diameter D2 of the bottom surface B₁₁₀₀ of each gate contact via 1100. Similarly, the length of the short-axis L11 of the top surface T₁₂₀₀ of each source/drain contact via 1200 is substantially equal to the length of the short-axis L13 of the top surface T₁₁₀₀ of each gate contact via 1100. On the other hand, the length of the long-axis L12 of the top surface T₁₂₀₀ of each source/drain contact via 1200 is greater than the length of the long-axis L14 of the top surface T₁₁₀₀ of each gate contact via 1100.

Referring to FIG. 4F, a dielectric layer 1300 and a plurality of routing patterns 1400 are formed on the dielectric layer 1000, the gate contact vias 1100, and the source/drain contact vias 1200 to obtain the semiconductor device 20. In some embodiments, the dielectric layer 1300 includes oxide such as silicon oxide, PSG, BSG, BPSG, a combination thereof, or the like. The dielectric layer 1300 may be deposited using, for example, spin-coating, FCVD, CVD, HDPCVD, PVD, SACVD, MLD, ALD, a combination thereof, or the like.

As illustrated in FIG. 4F, the routing patterns 1400 are embedded in the dielectric layer 1300. In some embodiments, the routing patterns 1400 are electrically connected to the gate contact vias 1100 and the source/drain contact vias 1200. For example, the routing patterns 1400 are in physical contact with the gate contact vias 1100 and the source/drain contact vias 1200 to render electrical connection with the gate contact vias 1100 and the source/drain contact vias 1200. In some embodiments, the routing patterns 1400 includes copper, copper alloys, nickel, aluminum, manganese, magnesium, silver, gold, tungsten, a combination of thereof, or the like. The routing patterns 1400 may be formed by, for example, electro-chemical plating process, CVD, PECVD, ALD, PVD, a combination thereof, or the like.

As mentioned above, the source/drain contact vias 1200 have larger top surfaces T₁₂₀₀. In other words, the contact area between the source/drain contact vias 1200 and the routing patterns 1400 may be increased. As such, the contact resistance may be lowered to improve the performance of the semiconductor device 20.

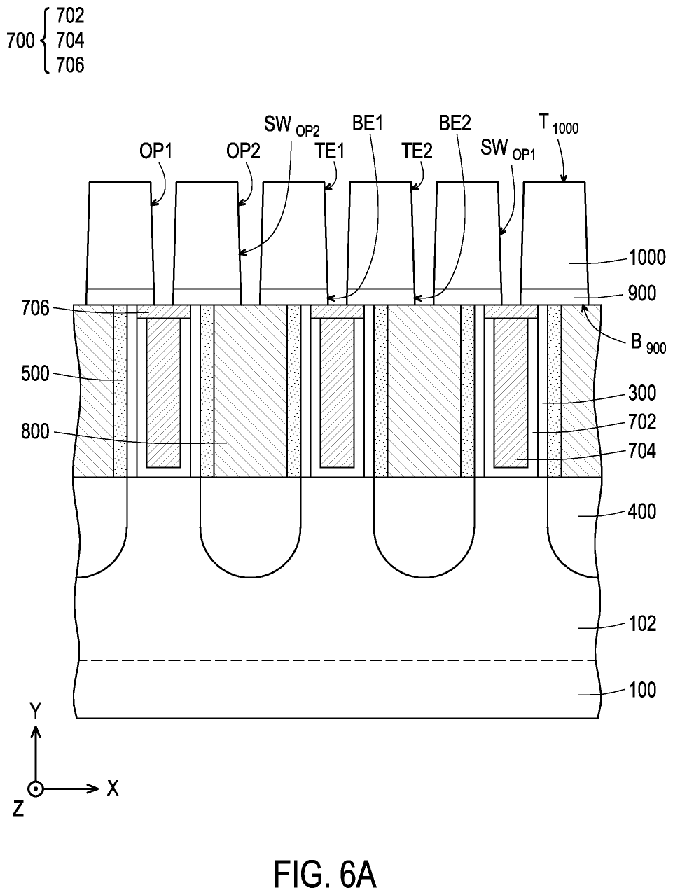

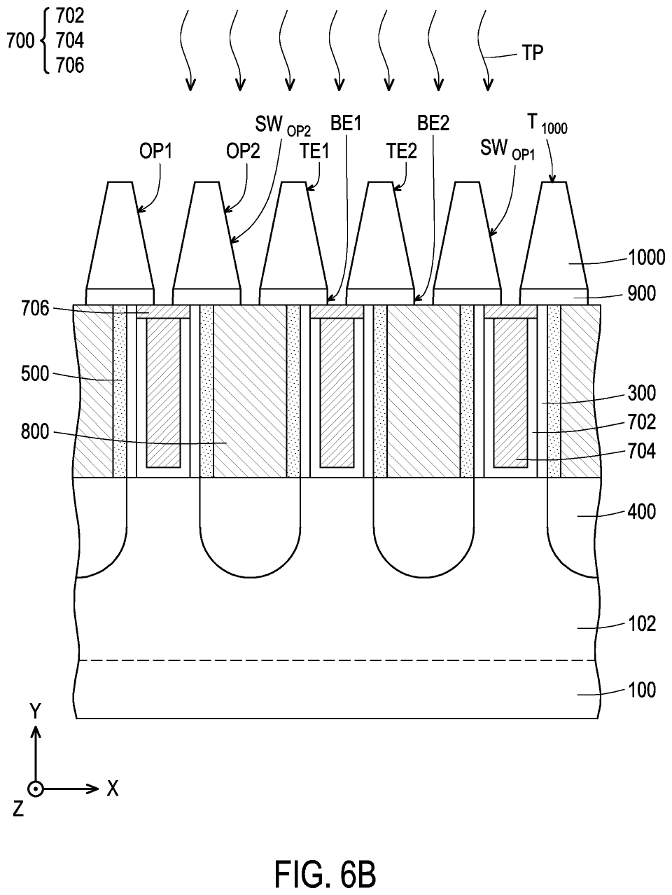

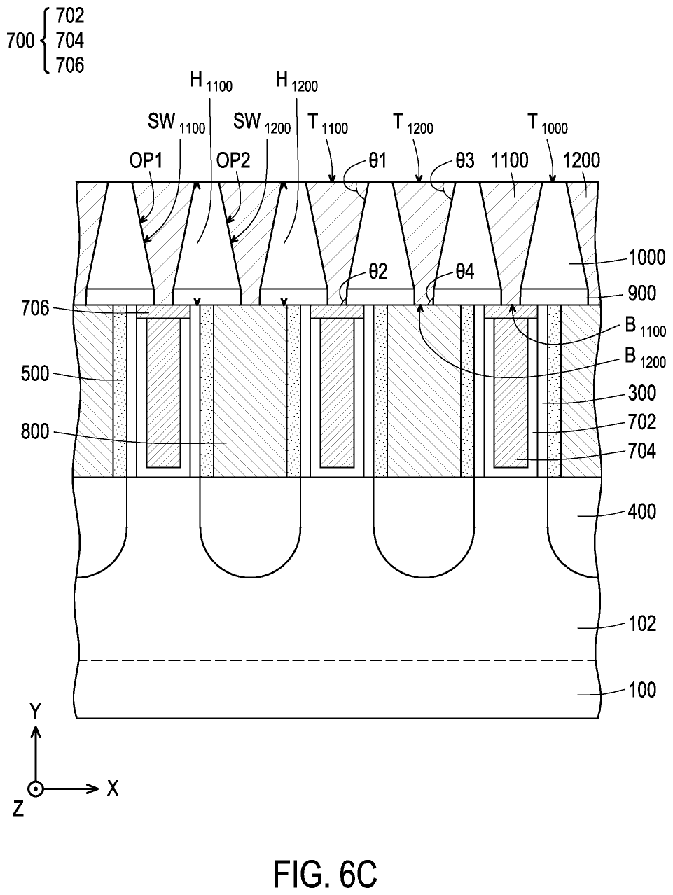

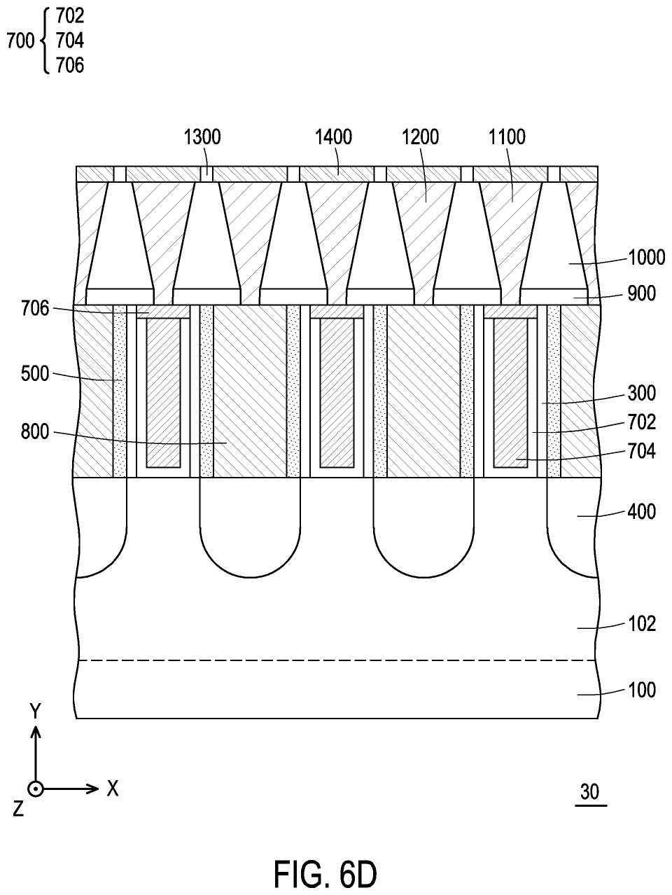

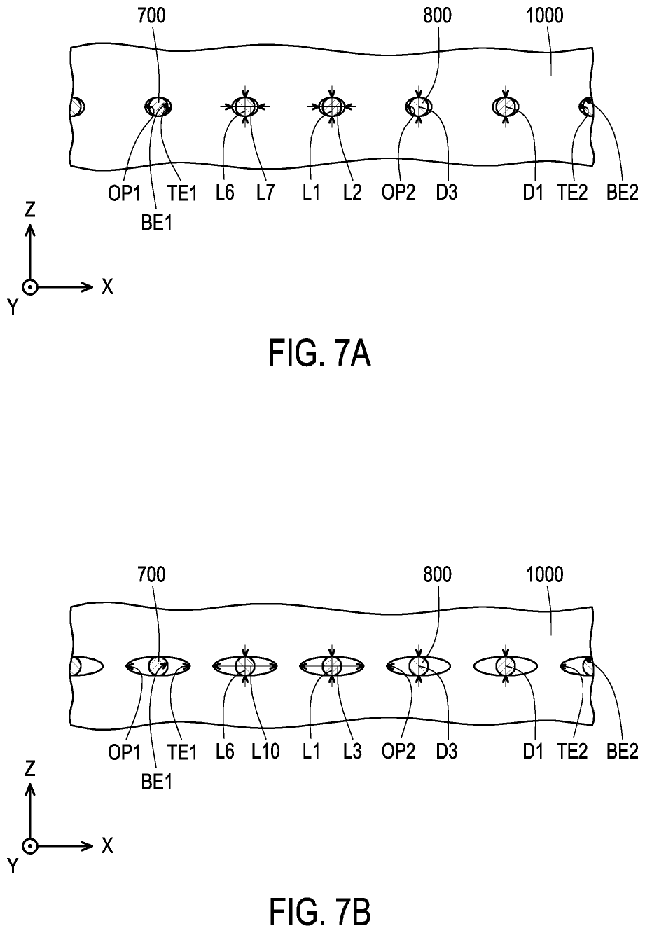

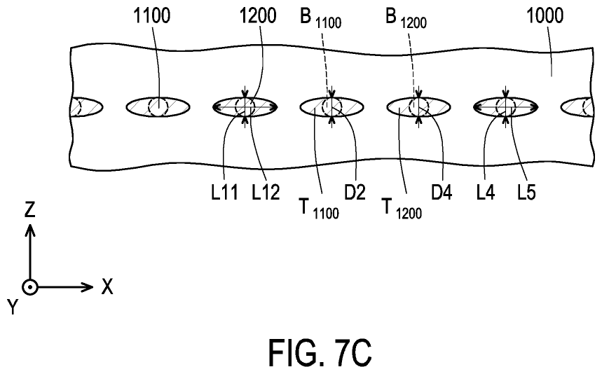

FIG. 6A to FIG. 6D are schematic cross-sectional views illustrating a manufacturing method of a semiconductor device 30 in accordance with some alternative embodiments of the disclosure. Referring to FIG. 6A to FIG. 6C, a plurality of gate contact vias 1110 and a plurality of source/drain contact vias 1200 are formed. The detailed configuration and formation method of the gate contact vias 1110 and the source/drain contact vias 1200 will be discussion below in conjunction with FIG. 6A to FIG. 6C and FIG. 7A to FIG. 7C.

FIG. 7A to FIG. 7C are schematic top views of FIG. 6A to FIG. 6C. Referring to FIG. 6A and FIG. 7A, similar processes as illustrated in FIG. 1A to FIG. 1G are performed. Thereafter, a plurality of openings OP1 and a plurality of openings OP2 are formed in the etch stop layer 900 and the dielectric layer 1000. In some embodiments, the openings OP1 and the openings OP2 are formed to penetrate through the etch stop layer 900 and the dielectric layer 1000. In some embodiments, each opening OP1 has a bottom end BE1 and a top end TE1 opposite to the bottom end BE1. Similarly, each opening OP2 has a bottom end BE2 and a top end TE2 opposite to the bottom end BE2. The top end TEL and the top end TE2 are in proximity to a top surface T₁₀₀₀ of the dielectric layer 1000 while the bottom end BE1 and the bottom end BE2 are in proximity to a bottom surface B₉₀₀ of the etch stop layer 900. In some embodiments, the locations of the openings OP1 correspond to the locations of the gate structures 700. For example, the bottom end BE1 of each opening OP1 exposes at least a portion of the corresponding gate structure 700. That is, the bottom end BE1 of each opening OP1 exposes at least a portion of the corresponding capping layer 706. On the other hand, the locations of the openings OP2 correspond to the locations of the source/drain contact patterns 800. For example, the bottom end BE2 of each opening OP2 exposes at least a portion of the corresponding source/drain contact pattern 800.

In some embodiments, sidewalls SW_{OP1} of each opening OP1 and sidewalls SW_{OP2} of each opening OP2 are substantially straight with a slight inclination with respect to the top surface T₁₀₀₀ of the dielectric layer 1000 and/or the bottom surface T₉₀₀ of the etch stop layer 900. Due to this slight inclination, the bottom end BE1 of each opening OP1 and the bottom end BE2 of each opening OP2 are circular while the top end TE1 of each opening OP1 and the top end TE2 of each opening OP2 are elliptical, as shown in FIG. 7A. In some embodiments, the top end TE1 is concentric with the bottom end BE1 in each opening OP1. Similarly, the top end TE2 is concentric with the bottom end BE2 in each opening OP2. In some embodiments, the bottom end BE1 of each opening OP1 has a diameter D1. On the other hand, the top end TE1 of each opening OP1 has a short-axis L1 extending along the Z-direction and a long-axis L2 extending along the X-direction. As illustrated in FIG. 7A, a length of the short-axis L1 of the top end TE1 is substantially equal to the diameter D1 of the bottom end BE1. Meanwhile, a length of the long-axis L2 of the top end TE1 is slightly greater than the diameter D1 of the bottom end BE1. In some embodiments, a ratio of an area of the bottom end BE1 of the opening OP1 to an area of the top end TE1 of the opening OP1 ranges from about 1:1.01 to about 1:1.05. In some embodiments, the bottom end BE2 of each opening OP2 has a diameter D3. On the other hand, the top end TE2 of each opening OP2 has a short-axis L6 extending along the Z-direction and a long-axis L7 extending along the X-direction. As illustrated in FIG. 7A, a length of the short-axis L6 of the top end TE2 is substantially equal to the diameter D3 of the bottom end BE2. Meanwhile, a length of the long-axis L7 of the top end TE2 is slightly greater than the diameter D3 of the bottom end BE2. In some embodiments, a ratio of an area of the bottom end BE2 of the opening OP2 to an area of the top end TE2 of the opening OP2 ranges from about 1:1.01 to about 1:1.05.

In some embodiments, each opening OP1 and each opening OP2 in FIG. 6A and FIG. 7A are formed by a lithography process followed by an etching process. The etching process includes, for example, a wet etching process or a dry etching process. Example of the wet etching process includes chemical etching and example of the dry etching process includes plasma etching. The plasma etching process includes ICP etching, CCP etching, or the like. When the etching is performed by ICP etching or CCP etching, the power and the bias supplied are respectively about 100 W to about 2000 W and about 0 W to about 1200 W. Meanwhile, the etching gas includes HBr, Cl₂, H₂, CH₄, N₂, He, Ne, Kr, CF₄, CHF₃, CH₃F, CH₂F₂, C₄F₈, C₄F₆, SF₆, N₂, O₂, Ar, a combination thereof, or the like.

Referring to FIG. 6A to FIG. 6B and FIG. 7A to FIG. 7B, the top end TE1 of each opening OP1 and the top end TE2 of each opening OP2 are enlarged. In some embodiments, a treating process TP is performed on the dielectric layer 1000 to remove a portion of the dielectric layer 1000 in proximity to the top end TE1 of each opening OP1 and the top end TE2 of each opening OP2, so as to enlarge the top end TE1 of each opening OP1 and the top end TE2 of each opening OP2. In some embodiments, the treating process TP includes reactive ion beam etching. In some embodiments, the power and the bias supplied during the reactive ion beam etching are respectively about 100 W to about 1000 W and about 0 kV to about 12 kV. Meanwhile, the etching gas includes He, Ne, Kr, Ar, CF₄, CHF₃, CH₃F, CH₂F₂, C₄F₈, C₄F₆, SF₆, O₂, a combination thereof, or the like. In some embodiments, since the reactive ion beam etching is an anisotropic etching, the enlargement of the openings OP1 and the openings OP2 is a one-directional enlargement. For example, as shown in FIG. 7B, the top end TE1 of each opening OP1 has the short-axis L1 extending along the Z-direction and a long-axis L3 extending along the X-direction. As shown in FIG. 7A and FIG. 7B, the length of the short-axis L1 remains unchanged while a length of the long-axis L3 in FIG. 7B is greater than the length of the long-axis L2 in FIG. 7A. In other words, the enlargement of the top end TE of each opening OP1 is only along the X-direction. In some embodiments, the top end TE2 of each opening OP2 has the short-axis L6 extending along the Z-direction and a long-axis L10 extending along the X-direction. As shown in FIG. 7A and FIG. 7B, the length of the short-axis L6 remains unchanged while a length of the long-axis L10 in FIG. 7B is greater than the length of the long-axis L7 in FIG. 7A. In other words, the enlargement of the top end TE2 of each opening OP2 is only along the X-direction. It should be noted that the treating process TP does not affect the bottom end BE1 of each opening OP1 and the bottom end BE2 of each opening OP2. In other words, the size and the shape of the bottom end BE1 of each opening OP1 and the bottom end BE2 of each opening OP2 remain unchanged.

As shown in FIG. 7B, the top end TE1 is concentric with the bottom end BE1 in each opening OP1. Similarly, the top end TE2 is concentric with the bottom end BE2 in each opening OP2. In some embodiments, the length of the short-axis L1 of the top end TE1 is substantially equal to the diameter D1 of the bottom end BE1. Meanwhile, a length of the long-axis L3 of the top end TE1 is greater than the diameter D1 of the bottom end BE1. For example, the length of the long-axis L3 of the top end TEL is greater than the diameter D1 of the bottom end BE1 by about 2 nm to about 6 nm. In some embodiments, after enlargement, a ratio of an area of the bottom end BE1 of the opening OP1 to an area of the top end TE1 of the opening OP1 ranges from about 1:1.2 to about 1:2. In some embodiments, the length of the short-axis L6 of the top end TE2 is substantially equal to the diameter D3 of the bottom end BE2. Meanwhile, a length of the long-axis L10 of the top end TE2 is greater than the diameter D3 of the bottom end BE2. For example, the length of the long-axis L10 of the top end TE2 is greater than the diameter D3 of the bottom end BE2 by about 2 nm to about 6 nm. In some embodiments, after enlargement, a ratio of an area of the bottom end BE2 of the opening OP2 to an area of the top end TE2 of the opening OP2 ranges from about 1:1.2 to about 1:2. In some embodiments, after the treating process TP, the sidewalls SW_{OP1} of each opening OP1 and the sidewalls SW_{OP2} of each opening OP2 are no longer straight. For example, at least a portion of each sidewall SW_{OP1} is curved, and each opening OP1 has a funnel shape. Similarly, at least of a portion of each sidewall SW_{OP2} is curved, and each opening OP2 has a funnel shape.

As illustrated in FIG. 6B, since one single treating process TP is performed, the top end TE1 of each opening OP1 and the top end TE2 of each opening OP2 are being enlarged simultaneously. However, the disclosure is not limited thereto. In some alternative embodiments, two distinct treating processes may be performed to separately enlarge the top end TE1 of each opening OP1 and the top end TE2 of each opening OP2.

Referring to FIG. 6C and FIG. 7C, a conductive material is filled into the openings OP1 and the openings OP2 to form the gate contact vias 1100 in the openings OP1 and the source/drain contact vias 1200 in the openings OP2. As illustrated in FIG. 6C, a height H₁₁₀₀ of each gate contact via 1100 is substantially equal to a height H₁₂₀₀ of each source/drain contact via 1200. In some embodiments, the conductive material includes metal or metal alloys, such as W, Cu, Co, Ni, Al, Rh, Ir, Ru, Mo, Os, Ag, Au, CuAl, NiAl, RuAl, VNi, VPt, AlSc, a combination thereof, or the like. In some embodiments, the conductive material is deposited into the openings OP1 and the openings OP2 through PVD, IBD, CVD, ALD, MBE, ECP, ELD, or the like. In some embodiments, in order to ensure the adhesion, an adhesion layer may be included in each gate contact via 1100 and each source/drain contact via 1200. A material of the adhesion layer includes nitride or oxide compounds of T, Ta, Mn, Nb, Cr, V, and Y.

In some embodiments, the gate contact vias 1100 are disposed on and electrically connected to the gate structures 700. For example, the gate contact vias 1100 penetrate through the dielectric layer 1000 and the etch stop layer 900 to be in physical contact with the gate structures 700 to render electrical connection with the gate structures 700. In some embodiments, the source/drain contact vias 1200 are disposed on and electrically connected to the source/drain contact patterns 800. For example, the source/drain contact vias 1200 penetrate through the dielectric layer 1000 and the etch stop layer 900 to be in physical contact with the source/drain contact patterns 800 to render electrical connection with the source/drain contact patterns 800.

In some embodiments, each gate contact via 1100 has a bottom surface B₁₁₀₀, a top surface T₁₁₀₀ opposite to the bottom surface B₁₁₀₀, and sidewalls SW₁₁₀₀ connecting the top surface T₁₁₀₀ and the bottom surface B₁₁₀₀. As illustrated in FIG. 6C, the bottom surface B₁₁₀₀ of each gate contact via 1100 is in physical contact with the corresponding gate structure 700. For example, the bottom surface B₁₁₀₀ of each gate contact via 1100 is in physical contact with the corresponding capping layer 706. Meanwhile, the top surface T₁₁₀₀ of each gate contact via 1100 is coplanar with the top surface T₁₀₀₀ of the dielectric layer 1000. As illustrated in FIG. 7C, the bottom surface B₁₁₀₀ of each gate contact via 1100 is circular in a top view, and the top surface T₁₁₀₀ of each gate contact via 1100 is elliptical in the top view. In some embodiments, the top surface T₁₁₀₀ is concentric with the bottom surface B₁₁₀₀ in each gate contact via 1100. In some embodiments, the bottom surface B₁₁₀₀ of each gate contact via 1100 has a diameter D2. On the other hand, the top surface T₁₁₀₀ of each gate contact via 1100 has a short-axis L4 extending along the Z-direction and a long-axis L5 extending along the X-direction. As illustrated in FIG. 7C, a length of the short-axis L4 of the top surface T₁₁₀₀ is substantially equal to the diameter D2 of the bottom surface B₁₁₀₀. Meanwhile, a length of the long-axis L5 of the top surface T₁₁₀₀ is greater than the diameter D2 of the bottom surface T₁₁₀₀. For example, the length of the long-axis L5 of the top surface T₁₁₀₀ is greater than the diameter D2 of the bottom surface T₁₁₀₀ by about 2 nm to about 6 nm. In some embodiments, a ratio of an area of the bottom surface B₁₁₀₀ of the gate contact via 1100 to an area of the top surface T₁₁₀₀ of the gate contact via 1100 ranges from about 1:1.2 to about 1:2.

In some embodiments, each source/drain contact via 1200 has a bottom surface B₁₂₀₀, a top surface T₁₂₀₀ opposite to the bottom surface B₁₂₀₀, and sidewalls SW₁₂₀₀ connecting the top surface T₁₂₀₀ and the bottom surface B₁₂₀₀. As illustrated in FIG. 6C, the bottom surface B₁₂₀₀ of each source/drain contact via 1200 is in physical contact with the corresponding source/drain contact pattern 800. Meanwhile, the top surface T₁₂₀₀ of each source/drain contact via 1200 is coplanar with the top surface T₁₀₀₀ of the dielectric layer 1000. As illustrated in FIG. 7C, the bottom surface B₁₂₀₀ of each source/drain contact via 1200 is circular in a top view, and the top surface T₁₂₀₀ of each source/drain contact via 1200 is elliptical in the top view. In some embodiments, the top surface T₁₂₀₀ is concentric with the bottom surface B₁₂₀₀ in each source/drain contact via 1200. In some embodiments, the bottom surface B₁₂₀₀ of each source/drain contact via 1200 has a diameter D4. On the other hand, the top surface T₁₂₀₀ of each source/drain contact via 1200 has a short-axis L11 extending along the Z-direction and a long-axis L12 extending along the X-direction. As illustrated in FIG. 7C, a length of the short-axis L11 of the top surface T₁₂₀₀ is substantially equal to the diameter D4 of the bottom surface B₁₂₀₀. Meanwhile, a length of the long-axis L12 of the top surface T₁₂₀₀ is greater than the diameter D4 of the bottom surface T₁₂₀₀. For example, the length of the long-axis L12 of the top surface T₁₂₀₀ is greater than the diameter D4 of the bottom surface T₁₂₀₀ by about 2 nm to about 6 nm. In some embodiments, a ratio of an area of the bottom surface B₁₂₀₀ of the source/drain contact via 1200 to an area of the top surface T₁₂₀₀ of the source/drain contact via 1200 ranges from about 1:1.2 to about 1:2.

In some embodiments, since the gate contact vias 1100 are formed by filling up the openings OP1, a contour of each gate contact via 1100 is substantially identical to a contour of each opening OP1. For example, at least of a portion of each sidewall SW₁₁₀₀ is curved, and each gate contact via 1100 has a funnel shape. As illustrated in FIG. 6C, an included angle θ1 between the top surface T₁₁₀₀ and the sidewall SW₁₁₀₀ of each gate contact via 1100 ranges from about 65° to about 80°, and an included angle θ2 between the bottom surface B₁₁₀₀ and the sidewall SW₁₁₀₀ of each gate contact via 1100 ranges from about 87° to about 90°. Similarly, since the source/drain contact vias 1200 are formed by filling up the openings OP2, a contour of each source/drain contact via 1200 is substantially identical to a contour of each opening OP2. For example, at least of a portion of each sidewall SW 1200 is curved, and each source/drain contact via 1200 has a funnel shape. As illustrated in FIG. 6C, an included angle θ3 between the top surface T₁₂₀₀ and the sidewall SW₁₂₀₀ of each source/drain contact via 1200 ranges from about 65° to about 80°, and an included angle θ4 between the bottom surface B₁₂₀₀ and the sidewall SW₁₂₀₀ of each source/drain contact via 1200 ranges from about 87° to about 90°.

As mentioned above, after the treating process TP, the top end TE1 of each opening OP1 and the top end TE2 of each opening OP2 are enlarged. As such, the process window for filling the conductive material into the openings OP1 and the openings OP2 to form the gate contact vias 1100 and the source/drain contact vias 1200 is enlarged, and the process complexity may be simplified. In addition, the enlarged top ends TE1 and the enlarged top ends TE2 render the gate contact vias 1100 and the source/drain contact vias 1200 to have larger top surfaces T₁₁₀₀ and T₁₂₀₀. In other words, the contact area between the gate contact vias 1100 and the subsequently formed elements and the contact area between the source/drain contact vias 1200 and the subsequently formed elements may be increased. As such, the contact resistance may be lowered to improve the device performance.

Referring to FIG. 6D, a dielectric layer 1300 and a plurality of routing patterns 1400 are formed on the dielectric layer 1000, the gate contact vias 1100, and the source/drain contact vias 1200 to obtain the semiconductor device 30. In some embodiments, the dielectric layer 1300 includes oxide such as silicon oxide, PSG, BSG, BPSG, a combination thereof, or the like. The dielectric layer 1300 may be deposited using, for example, spin-coating, FCVD, CVD, HDPCVD, PVD, SACVD, MLD, ALD, a combination thereof, or the like.

As illustrated in FIG. 6D, the routing patterns 1400 are embedded in the dielectric layer 1300. In some embodiments, the routing patterns 1400 are electrically connected to the gate contact vias 1100 and the source/drain contact vias 1200. For example, the routing patterns 1400 are in physical contact with the gate contact vias 1100 and the source/drain contact vias 1200 to render electrical connection with the gate contact vias 1100 and the source/drain contact vias 1200. In some embodiments, the routing patterns 1400 includes copper, copper alloys, nickel, aluminum, manganese, magnesium, silver, gold, tungsten, a combination of thereof, or the like. The routing patterns 1400 may be formed by, for example, electro-chemical plating process, CVD, PECVD, ALD, PVD, a combination thereof, or the like.

As mentioned above, the gate contact vias 1100 have larger top surfaces T₁₁₀₀ and the source/drain contact vias 1200 have larger top surfaces T₁₂₀₀. In other words, the contact area between the gate contact vias 1100 and the routing patterns 1400 and the contact area between the source/drain contact vias 1200 and the routing patterns 1400 may be increased. As such, the contact resistance may be lowered to improve the performance of the semiconductor device 30.

Please be noted that although FinFET devices have been used as an example throughout the entire disclosure, the disclosure is not limited thereto. The formation method and the shape of the gate contact vias 1100 and the source/drain contact vias 1200 are also applicable to other type of transistor device, such as planar transistors, gate-all-around (GAA) transistors, or the like.

In accordance with some embodiments of the disclosure, a semiconductor device includes a semiconductor substrate, a gate structure, strained layers, source/drain contact patterns, a gate contact via, and source/drain contact vias. The gate structure is disposed over the semiconductor substrate. The strained layers are disposed aside the gate structure. The source/drain contact patterns are disposed on and electrically connected to the strained layers. Top surfaces of the source/drain contact patterns are coplanar with a top surface of the gate structure. The gate contact via is disposed on and electrically connected to the gate structure. The source/drain contact vias are disposed on and electrically connected to the source/drain contact patterns.

In accordance with some alternative embodiments of the disclosure, a semiconductor device includes a semiconductor substrate, a gate structure, strained layers, source/drain contact patterns, a gate contact via, and source/drain contact vias. The gate structure is disposed over the semiconductor substrate. The strained layers are disposed aside the gate structure. The source/drain contact patterns are disposed on and electrically connected to the strained layers. The gate contact via is disposed on and electrically connected to the gate structure. The gate contact vias has a funnel shape. The source/drain contact vias are disposed on and electrically connected to the source/drain contact patterns.

In accordance with some embodiments of the disclosure, a manufacturing method of a semiconductor device includes at least the following steps. A semiconductor substrate is provided. A gate structure is formed over the semiconductor substrate. Strained layers are formed aside the gate structure. Source/drain contact patterns are formed on the strained layer. An etch stop layer and a dielectric layer are deposited on the gate structure and the source/drain contact patterns. A first opening penetrating through the etch stop layer and the dielectric layer is formed. The first opening has a bottom end exposing the gate structure and a top end opposite to the bottom end. The top end of the first opening is enlarged. A first conductive material is filled into the first opening to form a gate contact via in the first opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate;
a gate structure disposed over the semiconductor substrate;
strained layers disposed aside the gate structure;
source/drain contact patterns disposed on and electrically connected to the strained layers, wherein top surfaces of the source/drain contact patterns are coplanar with a top surface of the gate structure;
a gate contact via disposed on and electrically connected to the gate structure; and
source/drain contact vias disposed on and electrically connected to the source/drain contact patterns.

2. The semiconductor device of claim 1, wherein a height of the gate contact via is substantially equal to a height of each of the source/drain contact vias.

3. The semiconductor device of claim 1, wherein the gate contact via has a bottom surface in physical contact with the gate structure and a top surface opposite to the bottom surface, the top surface of the gate contact via is elliptical in a top view, and the bottom surface of the gate contact via is circular in the top view.

4. The semiconductor device of claim 3, wherein a ratio of an area of the bottom surface of the gate contact via to an area of the top surface of the gate contact via ranges from about 1:1.2 to about 1:2.

5. The semiconductor device of claim 3, wherein the top surface of the gate contact via has a long-axis and a short-axis, a length of the short-axis is substantially equal to a diameter of the bottom surface, and a length of the long-axis is greater than the diameter of the bottom surface.

6. The semiconductor device of claim 3, wherein the gate contact via further has a sidewall connecting the top surface and the bottom surface, and at least a portion of the sidewall is curved.

7. The semiconductor device of claim 6, wherein an included angle between the top surface and the sidewall of the gate contact via ranges from 65° to 80°, and an included angle between the bottom surface and the sidewall of the gate contact via ranges from 87° to 90°.

8. The semiconductor device of claim 1, wherein each of the source/drain contact vias has a bottom surface in physical contact with the corresponding source/drain contact pattern and a top surface opposite to the bottom surface, the top surface of each of the source/drain contact vias is elliptical in a top view, and the bottom surface of each of the source/drain contact vias is circular in the top view.

9. A semiconductor device, comprising:
a semiconductor substrate;
a gate structure disposed over the semiconductor substrate;
strained layers disposed aside the gate structure;
source/drain contact patterns disposed on and electrically connected to the strained layers;
a gate contact via disposed on and electrically connected to the gate structure, wherein the gate contact via has a funnel shape; and
source/drain contact vias disposed on and electrically connected to the source/drain contact patterns.

10. The semiconductor device of claim 9, wherein a height of the gate contact via is substantially equal to a height of each of the source/drain contact vias.

11. The semiconductor device of claim 9, wherein each of the source/drain contact vias has a funnel shape.

12. The semiconductor device of claim 9, wherein the gate contact via has a bottom surface in physical contact with the gate structure and a top surface opposite to the bottom surface, the top surface of the gate contact via is elliptical in a top view, and the bottom surface of the gate contact via is circular in the top view.

13. The semiconductor device of claim 12, wherein a ratio of an area of the bottom surface of the gate contact via to an area of the top surface of the gate contact via ranges from 1:1.2 to 1:2.

14. The semiconductor device of claim 12, wherein the top surface of the gate contact via has a long-axis and a short-axis, a length of the short-axis is substantially equal to a diameter of the bottom surface, and a length of the long-axis is greater than the diameter of the bottom surface by 2 nm to 6 nm.

15. The semiconductor device of claim 12, wherein the gate contact via further has a sidewall connecting the top surface and the bottom surface, an included angle between the top surface and the sidewall of the gate contact via ranges from 65° to 80°, and an included angle between the bottom surface and the sidewall of the gate contact via ranges from 87° to 90°.

16. A manufacturing method of a semiconductor device, comprising:
providing a semiconductor substrate;
forming a gate structure over the semiconductor substrate;
forming strained layers aside the gate structure;
forming source/drain contact patterns on the strained layers;
depositing an etch stop layer and a dielectric layer on the gate structure and the source/drain contact patterns;
forming a first opening penetrating through the etch stop layer and the dielectric layer, wherein the first opening has a bottom end exposing the gate structure and a top end opposite to the bottom end;
enlarging the top end of the first opening; and
filling a first conductive material into the first opening to form a gate contact via in the first opening.

17. The method of claim 16, wherein enlarging the top end of the first opening comprises performing a treating process to remove a portion of the dielectric layer in proximity to the top end of the first opening.

18. The method of claim 16, further comprising:
forming second openings penetrating through the etch stop layer and the dielectric layer, wherein each of the second openings has a bottom end exposing the corresponding source/drain contact pattern and a top end opposite to the bottom end; and
filling a second conductive material into the second openings to form source/drain contact vias in the second openings.

19. The method of claim 18, further comprising:
before filling the second conductive material into the second openings, enlarging the top ends of the second openings.

20. The method of claim 19, wherein enlarging the top end of the first opening and enlarging the top ends of the second openings are performed simultaneously.
